(19) United States
(12) Patent Application Publication
(10) Pub. No.: US 2026/0334031 A1
(43) Pub. Date: Oct. 22, 2026

(54) DISPLAY PANEL AND DISPLAY DEVICE

(71) Applicant: Yungu (Gu’an) Technology Co., Ltd., Langfang (CN)

(72) Inventors: Shuning HUANG, Langfang (CN); Jia LIU, Langfang (CN); Lipeng GAO, Langfang (CN); Lei MI, Langfang (CN)

(73) Assignee: Yungu (Gu’an) Technology Co., Ltd., Langfang (CN)

(21) Appl. No.: 19/696,271

(22) Filed: Jun. 2, 2026

(30) Foreign Application Priority Data
Jul. 29, 2025 (CN) 202511053325.0

(51) Int. Cl. H10K 59/131; H10K 59/126

(52) U.S. Cl. CPC H10K 59/131; H10K 59/126

(57) ABSTRACT

The present application discloses a display panel and a display device. The display panel has a first area and a second area, and includes: a base plate having a substrate and a number of driving circuits, first type signal lines, and second type signal lines disposed on the same side of the substrate; a number of light-emitting devices disposed on one side of the substrate, and at least a part of the first type signal lines and the second type signal lines are disposed in the second area, the first type signal lines are arranged at intervals from the driving circuits in the second area, and the second type signal lines are connected to at least one driving circuit in the second area. The first type signal lines include a first segment and a second segment that are located in the second area and connected to each other.

### CROSS REFERENCE TO RELATED APPLICATION

The present application claims priority to Chinese Patent Application No. 202511053325.0, filed on Jul. 29, 2025, which is incorporated herein by reference in its entirety.

### FIELD

The present application relates to the field of display technology, and in particular, to a display panel and a display device.

### BACKGROUND

Display panels such as Liquid Crystal Display (LCD) panels, Organic Light Emitting Display (OLED) panels, and display panels utilizing Light Emitting Diode (LED) devices are widely used in various consumer electronic products such as mobile phones, televisions, personal digital assistants, digital cameras, notebook computers, and desktop computers due to their advantages of high image quality, low power consumption, thin profile, and wide application range, and have become mainstream in display devices.

However, the operational performance of current display products needs to be improved.

### SUMMARY

Embodiments of the present application provide a display panel and a display device, aiming to improve the operational performance of the display panel.

An embodiment of the present application provides a display panel having a first region and a second region, the display panel including: a base plate including a substrate and a driving circuit, a first type of signal line, and a second type of signal line disposed on the same side of the substrate; a light-emitting device, disposed on one side of the substrate, the driving circuit being connected to the light-emitting device, and both the first region and the second region are provided with the driving circuit and the light-emitting device, at least a part of the first type of signal line and the second type of signal line are disposed in the second region, the first type of signal line is spaced apart from the driving circuit in the second region, the second type of signal line is connected to at least one driving circuit in the second region, the first type of signal line includes a first segment and a second segment located in the second region and connected to each other, the first segment is connected to the driving circuit in the first region, and the first segment is located between driving circuits adjacent in a first direction within the second region, a minimum distance between the second segment and the driving circuit on one side in the first direction is less than a minimum distance between the second segment and the driving circuit on the other side in the first direction.

An embodiment of the first aspect of the present application further provides a display panel having a first region and a second region, the display panel including: a base plate including a substrate and a driving circuit, a first type of signal line, and a second type of signal line disposed on the same side of the substrate; a light-emitting device, disposed on one side of the substrate, the driving circuit being connected to the light-emitting device, and both the first region and the second region are provided with the driving circuit and the light-emitting device, at least a part of the first type of signal line and the second type of signal line are disposed in the second region, the first type of signal line is spaced apart from the driving circuit in the second region, the second type of signal line is connected to at least one driving circuit in the second region, one part of the second type of signal line and another part of the second type of signal line are disposed in different layers within the second region, and one part of the first type of signal line and another part of the second type of signal line are disposed in different layers within the second region.

An embodiment of the first aspect of the present application further provides a display panel having a first region and a second region, the display panel including: a base plate including a substrate and a driving circuit, a first type of signal line, and a second type of signal line disposed on the same side of the substrate; a light-shielding structure, disposed on one side of the substrate, the light-shielding structure enclosing to form a light-shielding space, the driving circuit being located within the light-shielding space; a light-emitting device, disposed on one side of the substrate, the driving circuit being connected to the light-emitting device, and both the first region and the second region are provided with the driving circuit and the light-emitting device, at least a part of the first type of signal line and the second type of signal line are disposed in the second region, the first type of signal line is spaced apart from the driving circuit in the second region, and the first type of signal line is located outside the light-shielding space, the light-shielding structure is provided with a communication opening, the second type of signal line extends from outside the light-shielding space into the light-shielding space via the communication opening, the second type of signal line is connected to at least one driving circuit in the second region, the first type of signal line includes a first segment and a second segment located in the second region and connected to each other, the first segment is connected to the driving circuit in the first region, and the first segment is located between light-shielding structures adjacent in a first direction within the second region, a minimum distance between the second segment and the light-shielding structure on one side in the first direction is less than a minimum distance between the second segment and the light-shielding structure on the other side in the first direction, and a compensation capacitor is formed between an adjacent second segment and the light-shielding structure.

An embodiment of the present application provides a display device, the display device including the display panel according to any of the above embodiments.

In a display panel provided by an embodiment of the present application, the display panel includes a base plate and a light-emitting device, the light-emitting device is disposed on one side of the substrate, the base plate includes a substrate and a driving circuit, a first type of signal line, and a second type of signal line disposed on the same side of the substrate, the driving circuit is connected to the light-emitting device, enabling the driving circuit to drive the light-emitting device for light-emitting display. The display panel has a first region and a second region, both the first region and the second region are provided with the driving circuit and the light-emitting device, enabling both the first region and the second region to be used for light-emitting display.

Both the first type of signal lines and the second type of signal lines can be used to connect with the driving circuits and provide signals to the driving circuits, thereby facilitating the operation of the driving circuits. At least a part of the first type of signal line and the second type of signal line are disposed in the second region. The second type of signal lines are connected to at least one driving circuit within the second region, enabling the second type of signal lines to transmit signals to the driving circuits in the second region. The first type of signal lines are spaced apart from the driving circuits in the second region. The first type of signal lines include a first segment and a second segment located in the second region and connected to each other. The first segment is connected to the driving circuits in the first region. The first type of signal lines may be used solely to transmit signals to the driving circuits in the first region, meaning that the first type of signal lines only extend through the second region but are not used to transmit signals to the driving circuits in the second region. By arranging the first segment between adjacent driving circuits in the first direction within the second region, it facilitates the connection between the first segment and the driving circuits in the first region located between adjacent second type of signal lines in the first direction. By setting the minimum distance between the second segment in the second region and the driving circuits on one side in the first direction to be less than the minimum distance between the second segment and the driving circuits on the other side in the first direction, the second segment, which is not directly connected to the driving circuits in the second region, can be offset toward the driving circuits on one side in the first direction. This ensures that within the second region, the electric field environment around the first type of signal lines approximates that around the second type of signal lines. Consequently, during signal transmission, the operational stability of the first type of signal lines approximates that of the second type of signal lines, which helps improve the display uniformity and operational stability of the display panel.

### BRIEF DESCRIPTION OF THE DRAWINGS

To more clearly illustrate the embodiments of the present application, the following briefly introduces the accompanying drawings required for describing the embodiments. The following drawings only show certain embodiments of the present application and should not be considered as limiting the scope.

FIG. 1 is a schematic partial cross-sectional view of a display panel provided by an embodiment of the present application;

FIG. 2 is a schematic structural diagram of a driving circuit provided by an embodiment of the present application;

FIG. 3 is a schematic structural diagram of a display panel provided by an embodiment of the present application;

FIG. 4 is a schematic layout diagram of driving circuits provided by an embodiment of the present application;

FIG. 5 is a schematic diagram showing the positions of driving circuits, first type signal lines, and second type signal lines provided by an embodiment of the present application;

FIG. 6 is a schematic partial cross-sectional view of a display panel provided by another embodiment of the present application;

FIG. 7 is a schematic partial cross-sectional view of a display panel provided by yet another embodiment of the present application;

FIG. 8 is a schematic partial cross-sectional view of a display panel provided by still another embodiment of the present application;

FIG. 9 is a schematic partial cross-sectional view of a display panel provided by a further embodiment of the present application;

FIG. 10 is a schematic partial cross-sectional view of a display panel provided by another further embodiment of the present application;

FIG. 11 is a schematic diagram showing the positions of a light-shielding structure, driving circuits, first type signal lines, and second type signal lines provided by an embodiment of the present application;

FIG. 12 is a schematic partial cross-sectional view of a display panel provided by still another further embodiment of the present application; and

FIG. 13 is a schematic diagram showing the positions of a light-shielding structure, driving circuits, first type signal lines, second type signal lines, and third type signal lines provided by an embodiment of the present application.

### DETAILED DESCRIPTION

The features and exemplary embodiments of various aspects of the present application will be described below. To make the objectives, embodiments, and advantages of the present application clearer, the present application will be further described below with reference to the accompanying drawings and specific embodiments. The specific embodiments described herein are only configured to explain the present application and are not configured to limit the present application. The present application can be implemented without some of these specific details. The following description of the embodiments is provided to give a better understanding of the present application by illustrating examples of the present application.

In this document, relational terms such as first and second are used only to distinguish one entity or operation from another entity or operation, and do not necessarily require or imply any such actual relationship or order between these entities or operations. Furthermore, the term “comprising,” “including,” or any other variation thereof is intended to cover a non-exclusive inclusion, and a process, method, article, or device that includes a series of elements includes not only those elements but also other elements not explicitly listed, or elements inherent to such process, method, article, or device. Without further limitation, an element defined by the phrase “comprising . . . ” does not preclude the presence of additional identical elements in the process, method, article, or device that includes the element.

When describing the structure of a component, when one layer or region is referred to as being “on” or “above” another layer or region, it can mean directly on the other layer or region, or intervening layers or regions may also be present. Moreover, if the component is flipped, the layer or region will be “under” or “below” the other layer or region.

Embodiments of the present application provide a display panel and a display device. Various embodiments of the display panel and display device will be described below with reference to the accompanying drawings.

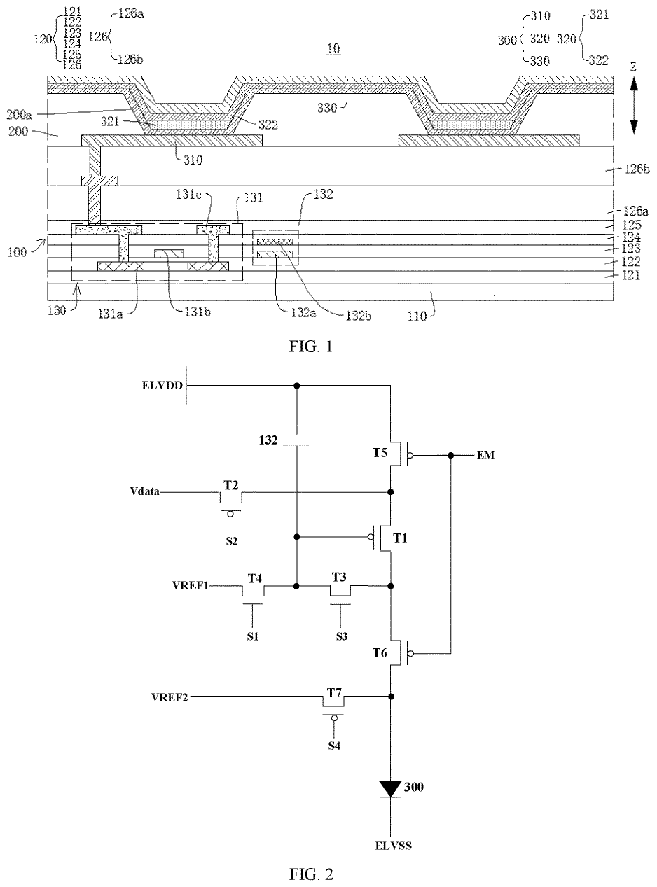

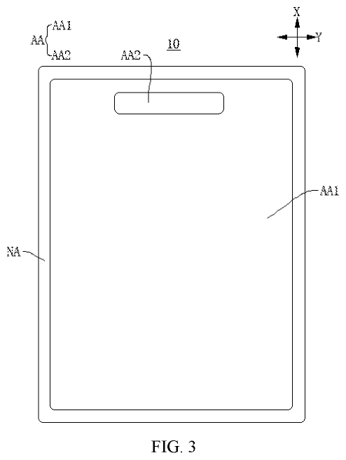

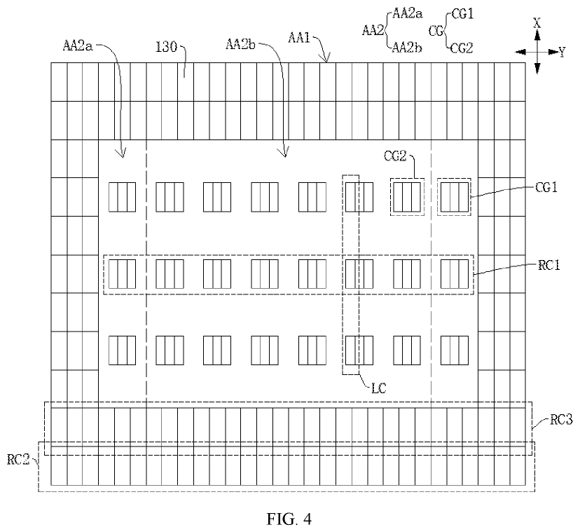

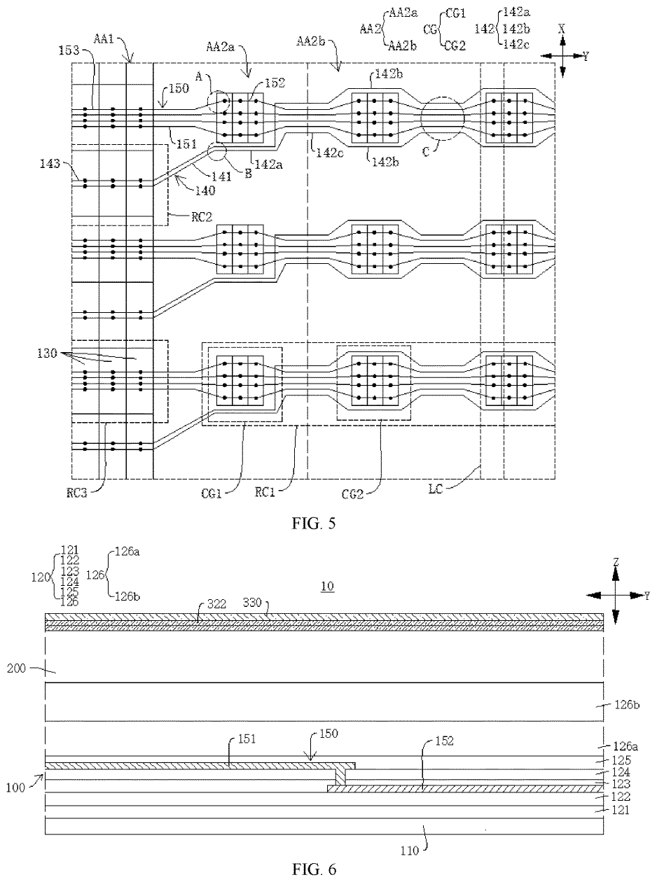

FIG. 1 is a schematic partial cross-sectional view of a display panel 10 provided by an embodiment of the present application. FIG. 2 is a schematic structural diagram of a driving circuit 130 provided by an embodiment of the present application. FIG. 3 is a schematic structural diagram of a display panel 10 provided by an embodiment of the present application. FIG. 4 is a schematic layout diagram of a driving circuit 130 provided by an embodiment of the present application. FIG. 5 is a schematic diagram showing the positions of a driving circuit 130, a first type of signal line 140, and a second type of signal line 150 provided by an embodiment of the present application.

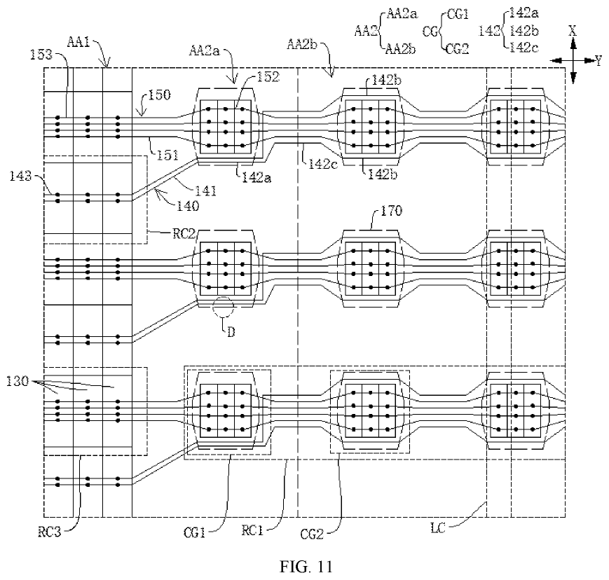

In some drawings, the driving circuit 130 is schematically shown with a solid-line box. The line widths and overlapping conditions of the signal lines in FIG. 11 are not shown. FIG. 1 may be a schematic partial cross-sectional view of the display panel 10 within a first region AA1. The X direction in the figure may indicate a first direction X, the Y direction in the figure may indicate a second direction Y, and the Z direction in the figure may indicate a thickness direction Z of the display panel 10. The first direction X, the second direction Y, and the thickness direction Z of the display panel 10 may intersect pairwise. In an embodiment, the first direction X, the second direction Y, and the thickness direction Z of the display panel 10 may be pairwise perpendicular.

As shown in FIG. 1 to FIG. 5, an embodiment of the present application provides a display panel 10 having a first region AA1 and a second region AA2. The display panel 10 includes: a base plate 100, including a substrate 110 and a driving circuit 130, a first type of signal line 140, and a second type of signal line 150 disposed on the same side of the substrate 110; a light-emitting device 300 disposed on one side of the base plate 100, the driving circuit 130 being connected to the light-emitting device 300. The driving circuit 130 and the light-emitting device 300 are disposed in both the first region AA1 and the second region AA2. At least a part of the first type of signal line 140 and the second type of signal line 150 are disposed in the second region AA2. In an embodiment, at least a part of at least one of the first type of signal lines 140 and at least a part of at least one of the second type of signal lines 150 are disposed in the second region AA2. In another embodiment, some of the first type of signal lines 140 and some of the second type of signal lines 150 are disposed in the second region AA2.

The first type of signal line 140 is spaced apart from the driving circuit 130 in the second region AA2. The second type of signal line 150 is connected to at least one driving circuit 130 in the second region AA2. The first type of signal line 140 includes a first segment 141 and a second segment 142 located in the second region AA2 and connected to each other. The first segment 141 is connected to the driving circuit 130 in the first region AA1, and the first segment 141 is located between driving circuits 130 adjacent in the first direction X within the second region AA2. A minimum distance between the second segment 142 and the driving circuit 130 on one side in the first direction X is less than a minimum distance between the second segment 142 and the driving circuit 130 on the other side in the first direction X.

In an embodiment, the display panel 10 provided by the embodiment of the present application may be a display panel 10 that emits light based on Liquid Crystal Display (LCD) principles, or the display panel 10 may be a display panel 10 that emits light based on Organic Light Emitting Diode (OLED) light-emitting display principles, or the display panel 10 may be a display panel 10 that emits light based on Quantum Dot Light Emitting Diodes (QLED) light-emitting display principles, which is not, in one embodiment, limited in the present application.

Subsequent embodiments will be described by taking the display panel 10 provided by the embodiment of the present application as an example of a display panel 10 that emits light based on Organic Light Emitting Diode (OLED) light-emitting display principles.

In a display panel 10 provided by an embodiment of the present application, the display panel 10 includes a base plate 100 and a light-emitting device 300. The light-emitting device 300 is disposed on one side of the base plate 100. The base plate 100 includes a substrate 110 and a driving circuit 130, a first type of signal line 140, and a second type of signal line 150 disposed on the same side of the substrate 110. The driving circuit 130 is connected to the light-emitting device 300, enabling the driving circuit 130 to drive the light-emitting display of the light-emitting device 300.

In an embodiment, the driving circuit 130 may include a transistor 131, a storage capacitor 132, and traces for connecting various devices, among others. The transistor 131 may include a semiconductor structure 131a, a gate 131b located on a side of the semiconductor structure 131a away from the substrate 110, and a source-drain electrode 131c located on a side of the gate 131b away from the substrate 110. The storage capacitor 132 may include a first electrode plate 132a and a second electrode plate 132b located on a side of the first electrode plate 132a away from the substrate 110.

In an embodiment, there are various operating principles and circuit structure configurations for the driving circuit 130. The driving circuit 130 may be a circuit structure such as 2T1C, 4T1C, 7T1C, 7T2C, 8T1C, or 8T2C.

In an embodiment, the transistor 131 may include a driving transistor T1, a data writing transistor T2, a threshold compensation transistor T3, a first reset transistor T4, a second reset transistor T7, a first control transistor T5, a second control transistor T6, and a second reset transistor T7. The base plate 100 may further include a first power supply voltage signal line ELVDD, a second power supply voltage signal line ELVSS, a data signal line Vdata, a first reset signal line VREF1, a second reset signal line VREF2, a light emission control signal line EM, a first scan signal line S1, a second scan signal line S2, a third scan signal line S3, and a fourth scan signal line S4.

A first terminal of the first control transistor T5 may be electrically connected to the second electrode plate 132b of the storage capacitor 132, and both the first terminal of the first control transistor T5 and the second electrode plate 132b of the storage capacitor 132 may be electrically connected to the first power supply voltage signal line ELVDD. The first power supply voltage signal line ELVDD may provide a positive power supply voltage signal to the first control transistor T5 and the storage capacitor 132. A first terminal of the data writing transistor T2 may be electrically connected to the data signal line Vdata. The data signal line Vdata may provide a data signal to the data writing transistor T2. A second terminal of the data writing transistor T2, a second terminal of the first control transistor T5, and a first terminal of the driving transistor T1 may be electrically connected to each other.

A second terminal of the driving transistor T1 is electrically connected to a first terminal of the threshold compensation transistor T3. Further by way of example, the second terminal of the driving transistor T1, the first terminal of the threshold compensation transistor T3, and a first terminal of the second control transistor T6 may be electrically connected to each other. A first terminal of the first reset transistor T4 may be electrically connected to the first reset signal line VREF1. The first reset signal line VREF1 may provide a first reset signal to the first reset transistor T4. A second terminal of the threshold compensation transistor T3, a control terminal of the driving transistor T1, a second terminal of the first reset transistor T4, and the first electrode plate 132a of the storage capacitor 132 may be electrically connected to each other.

A first terminal of the second reset transistor T7 may be electrically connected to the second reset signal line VREF2. The second reset signal line VREF2 may provide a second reset signal to the second reset transistor T7. A second terminal of the second reset transistor T7, a second terminal of the second control transistor T6, and a first electrode 310 of the light-emitting device 300 may be electrically connected to each other. A second electrode 330 of the light-emitting device 300 may be electrically connected to the second power supply voltage signal line ELVSS (which may be, in an embodiment, a negative power supply voltage signal line).

A control terminal of the second control transistor T6 may be electrically connected to a control terminal of the first control transistor T5, and both the control terminal of the second control transistor T6 and the control terminal of the first control transistor T5 may be electrically connected to the light emission control signal line EM. A control terminal of the first reset transistor T4 may be electrically connected to the first scan signal line S1. A control terminal of the data writing transistor T2 may be electrically connected to the second scan signal line S2. A control terminal of the threshold compensation transistor T3 may be electrically connected to the third scan signal line S3. A control terminal of the second reset transistor T7 may be electrically connected to the fourth scan signal line S4.

In an embodiment, the base plate 100 may further include a plurality of insulating film layers 120 stacked on the substrate 110. Device structures in the driving circuit 130 may be disposed between adjacent insulating film layers 120 to facilitate the arrangement of various device structures in the driving circuit 130. As an example, in a direction away from the substrate 110, the base plate 100 may further include a first insulating layer 121, a second insulating layer 122, a third insulating layer 123, a fourth insulating layer 124, a fifth insulating layer 125, and a sixth insulating layer 126 sequentially stacked. The semiconductor structure 131a may be disposed between the first insulating layer 121 and the second insulating layer 122. The gate 131b and the first electrode plate 132a may be located between the second insulating layer 122 and the third insulating layer 123. The second electrode plate 132b may be located between the third insulating layer 123 and the fourth insulating layer 124. The source-drain electrode 131c may be located between the fourth insulating layer 124 and the fifth insulating layer 125. The sixth insulating layer 126 may serve as a planarization layer, meaning that a surface of the sixth insulating layer 126 away from the substrate 110 may be relatively flat, facilitating subsequent preparation of other film layers on the base plate 100. The light-emitting device 300 may be disposed on a side of the sixth insulating layer 126 away from the substrate 110.

In an embodiment, the sixth insulating layer 126 may include a first sub-insulating layer 126a and a second sub-insulating layer 126b located on a side of the first sub-insulating layer 126a away from the substrate 110, and the space between the first sub-insulating layer 126a and the second sub-insulating layer 126b can also be used to arrange device structures, thereby further facilitating the arrangement of various device structures in the base plate 100.

In an embodiment, a single driving circuit 130 may correspond to a single light-emitting device 300, meaning that a single driving circuit 130 may be used to drive the light emission display of a single light-emitting device 300. In an embodiment, both the number of driving circuits 130 and the number of light-emitting devices 300 may be multiple. The multiple driving circuits 130 and the multiple light-emitting devices 300 may be arranged in an array along a first direction X and a second direction Y. Here, the first direction X may be a column direction in which the driving circuits 130 and the light-emitting devices 300 are arranged, and the second direction Y may be a row direction in which the driving circuits 130 and the light-emitting devices 300 are arranged.

In an embodiment, in a direction away from the base plate 100, the light-emitting device 300 includes a first electrode 310, a light-emitting functional layer 320, and a second electrode 330 sequentially stacked.

In an embodiment, the light-emitting functional layer 320 may include a light-emitting structure 321 and a common layer 322 disposed on at least one side of the light-emitting structure 321 in the thickness direction Z of the display panel 10. In an embodiment, the common layer 322 may be disposed on both sides of the light-emitting structure 321 in the thickness direction Z of the display panel 10. The common layer 322 disposed on the side of the light-emitting structure 321 facing the base plate 100 may include a hole injection layer (HIL) and a hole transport layer (HTL). The common layer 322 disposed on the side of the light-emitting structure 321 away from the base plate 100 may include an electron injection layer (EIL) and an electron transport layer (ETL).

In an embodiment, the first electrode 310 and the second electrode 330 may serve as pixel electrodes of the display panel 10. One of the first electrode 310 and the second electrode 330 may serve as an anode, and the other may serve as a cathode to drive the light-emitting functional layer 320 to emit light. In the embodiments of the present application, the first electrode 310 is taken as an example of the anode of the display panel 10, and the second electrode 330 is taken as an example of the cathode of the display panel 10.

In an embodiment, the connection between the driving circuit 130 and the light-emitting device 300 may refer to that the source and drain 131c of some transistors 131 in the driving circuit 130 may be connected to the first electrode 310 of the light-emitting device 300, and the driving circuit 130 can provide a driving current to the first electrode 310 to drive the light-emitting display of the light-emitting device 300.

In an embodiment, the second electrodes 330 of the respective light-emitting devices 300 may be electrically connected to each other, thereby facilitating control of the display panel 10. In an embodiment, the second electrodes 330 of the respective light-emitting devices 300 may be integrally formed. In an embodiment, the common layers 322 of the respective light-emitting devices 300 may be integrally formed to facilitate the fabrication of the display panel 10.

In an embodiment, the display panel 10 may further include a pixel defining layer 200 disposed on a side of the first electrode 310 away from the base plate 100. The pixel defining layer 200 may be provided with pixel openings 200a. The light-emitting functional layer 320 and the second electrode 330 may extend from inside the pixel openings 200a to outside the pixel openings 200a. At least a part of the surface of the first electrode 310 away from the base plate 100 may be exposed from the pixel openings 200a and connected to the light-emitting functional layer 320. The pixel defining layer 200 may be used to participate in defining sub-pixels of the display panel 10.

The display panel 10 has a first region AA1 and a second region AA2. Both the first region AA1 and the second region AA2 are provided with driving circuits 130 and light-emitting devices 300, and both the first region AA1 and the second region AA2 can be used for light-emitting display.

In an embodiment, the display panel 10 may include a display area AA and a non-display area NA surrounding at least a portion of the display area AA. The display area AA may include the first region AA1 and the second region AA2.

In an embodiment, under the premise that both the first region AA1 and the second region AA2 can be used to realize the display function of the display panel 10, the structure of the display panel 10 in the first region AA1 and the structure of the display panel 10 in the second region AA2 may have certain differences, and the display panel 10 in the second region AA2 may have other functions compared to the display panel 10 in the first region AA1.

In an embodiment, the light transmittance of the display panel 10 located in the second region AA2 is greater than that of the display panel 10 located in the first region AA1, and the display panel 10 located in the second region AA2 can be used to participate in light-sensing work. In an embodiment, when the display panel 10 is applied to a display device, a photosensitive component in the display device for sensing light may be correspondingly disposed under the second region AA2. The second region AA2 with higher light transmittance is less likely to block light significantly, facilitating better light sensing by the photosensitive component. The photosensitive component may include at least one of components capable of sensing light, such as a face recognition sensor, a camera, an under-screen fingerprint recognition module, an infrared light emitting diode (IR-LED) proximity sensor, a distance sensor, etc.

In an embodiment, there are various ways to achieve that the light transmittance of the display panel 10 located in the second region AA2 is greater than that of the display panel 10 located in the first region AA1. As an example, the sub-pixel arrangement density in the second region AA2 may be less than the sub-pixel arrangement density in the first region AA1, and/or the size of sub-pixels in the second region AA2 may be smaller than the size of sub-pixels in the first region AA1.

In an embodiment, the arrangement density of driving circuits 130 in the second region AA2 is less than the arrangement density of driving circuits 130 in the first region AA1, and/or the arrangement density of light-emitting devices 300 in the second region AA2 is less than the arrangement density of light-emitting devices 300 in the first region AA1, and/or the size of driving circuits 130 in the second region AA2 may be smaller than the size of driving circuits 130 in the first region AA1, and/or the size of light-emitting devices 300 in the second region AA2 may be smaller than the size of light-emitting devices 300 in the first region AA1.

In an embodiment, the sub-pixel arrangement density in the second region AA2 may be half of the sub-pixel arrangement density in the first region AA1, and the display panel 10 located in the second region AA2 can have good light transmittance.

In an embodiment, there are various relative positional relationships between the first region AA1 and the second region AA2. In an embodiment, the first region AA1 may surround at least a portion of the second region AA2 (e.g., a portion of the first region AA1 may be located on at least one side of the second region AA2 in the first direction X, and a portion of the first region AA1 may be located on both sides of the second region AA2 in the second direction Y), and the first region AA1 can have a larger size, which is beneficial for improving the display effect of the display panel 10.

In an embodiment, the number of the second area AA2 may be one, which facilitates control over sub-pixel display within the second area AA2. In an embodiment, when the display panel 10 is applied to a display device, by setting the number of the second area AA2 to one, it facilitates control by the control chip in the display device over sub-pixel display within the second area AA2.

Both the first type of signal lines 140 and the second type of signal lines 150 can be used to connect with the driving circuits 130 and to provide signals to the driving circuits 130, thereby facilitating the operation of the driving circuits 130.

In an embodiment, the first type of signal lines 140 and the second type of signal lines 150 can be used to transmit at least one of a scan signal, a light emission control signal, and a reset signal. That is, the first type of signal lines 140 and the second type of signal lines 150 can be multiplexed as at least one of the first scan signal line S1, the second scan signal line S2, the third scan signal line S3, the light emission control signal line EM, the first reset signal line VREF1, and the second reset signal line VREF2 in the above embodiments, which is not, in one embodiment, limited in this application.

In an embodiment, the number of the first type of signal lines 140 may be at least two, and different first type of signal lines 140 can be used to transmit different signals. The number of the second type of signal lines 150 may be at least two, and different second type of signal lines 150 can be used to transmit different signals.

At least a part of the first type of signal line 140 and the second type of signal line 150 are disposed in the second area AA2, and the second type of signal lines 150 are connected to at least one driving circuit 130 within the second area AA2, enabling the second type of signal lines 150 to transmit signals to the driving circuits 130 within the second area AA2.

In an embodiment, the display panel 10 includes circuit groups CG located within the second area AA2. A single circuit group CG includes at least one driving circuit 130, and there are multiple circuit groups CG. The multiple circuit groups CG are arrayed in the first direction X and the second direction Y. The second type of signal lines 150 can be used to connect with the driving circuits 130 in the circuit groups CG (in an embodiment, all driving circuits 130 in the circuit groups CG), enabling the second type of signal lines 150 to transmit signals to the driving circuits 130 within the circuit groups CG in the second area AA2.

In an embodiment, each circuit group CG corresponds to a repeated pixel unit group. The repeated pixel unit group may include multiple light-emitting devices 300, and the circuit group CG may include multiple driving circuits 130 correspondingly arranged with the light-emitting devices 300.

In an embodiment, when a repeated pixel unit group includes one light-emitting device 300 with a red light emission color, one light-emitting device 300 with a green light emission color, and one light-emitting device 300 with a blue light emission color, a single circuit group CG may include three driving circuits 130. Further exemplarily, a single circuit group CG may include one driving circuit 130 connected to a light-emitting device 300 with a red light emission color, one driving circuit 130 connected to a light-emitting device 300 with a green light emission color, and one driving circuit 130 connected to a light-emitting device 300 with a blue light emission color.

In an embodiment, at least one second type of signal line 150 is connected to at least two circuit groups CG adjacent in the second direction Y. Exemplarily, the display panel 10 includes a first circuit row RC1 located in the second area AA2. The first circuit row RC1 includes circuit groups CG located in the same row in the second direction Y. A single second type of signal line 150 can be connected to the driving circuits 130 of all circuit groups CG in the first circuit row RC1, enabling the single second type of signal line 150 to provide signals to the driving circuits 130 located in the same row in the second direction Y within the second area AA2.

In an embodiment, the display panel 10 further includes a second circuit row RC2 and a third circuit row RC3 arranged in staggered rows. The second circuit row RC2 includes a part of the driving circuits 130 located in the same row in the second direction Y within the first area AA1, and the third circuit row RC3 includes another part of the driving circuits 130 located in the same row in the second direction Y within the first area AA1. A part of the driving circuit 130 or some of the driving circuits 130 are located in the same row in the second direction Y within the first area AA1.

In an embodiment, the staggered arrangement of the second circuit row RC2 and the third circuit row RC3 may refer to the alternating arrangement of the second circuit row RC2 and the third circuit row RC3 in the first direction X.

In an embodiment, one of the second circuit row RC2 and the third circuit row RC3 may be located in an odd-numbered row in the arrangement of driving circuits 130 within the display panel 10, and the other may be located in an even-numbered row in the arrangement of driving circuits 130 within the display panel 10, which is not, in one embodiment, limited in this application. Subsequent embodiments are described with the example where the second circuit row RC2 is located in an even-numbered row in the arrangement of driving circuits 130 within the display panel 10, and the third circuit row RC3 is located in an odd-numbered row in the arrangement of driving circuits 130 within the display panel 10.

In an embodiment, the first circuit row RC1 may be arranged along the second direction Y with the third circuit row RC3, meaning the first circuit row RC1 and the third circuit row RC3 may be located in the same row (in an embodiment, both the first circuit row RC1 and the third circuit row RC3 are located in odd-numbered rows in the arrangement of driving circuits 130 within the display panel 10). Exemplarily, the first circuit row RC1 may be located between third circuit rows RC3 within the first area AA1 on both sides of the second area AA2 in the second direction Y.

In an embodiment, the second circuit row RC2 and the first circuit row RC1 may not be located in the same row.

In an embodiment, a single second type of signal line 150 is connected to two driving circuits 130 located on both sides of the second area AA2 in the second direction Y within the third circuit row RC3. This enables signals from the third circuit row RC3 located on one side of the second area AA2 in the first direction X to be transmitted to the driving circuits 130 within the second area AA2 via the second type of signal line 150, and also enables signals from the third circuit row RC3 located on one side of the second area AA2 in the first direction X to be transmitted to the driving circuits 130 of the third circuit row RC3 located on the other side of the second area AA2 in the first direction X via the second type of signal line 150, thereby facilitating control over the operation of the display panel 10.

In an embodiment, the second type of signal line 150 includes a third segment 151 and a fourth segment 152 located in the second region AA2 and connected to each other. In an embodiment, the third segment 151 may be connected to two driving circuits 130 located on both sides of the second region AA2 in the second direction Y in the third circuit row RC3, and the fourth segment 152 may be connected to at least one driving circuit 130 in the second region AA2.

The first type of signal line 140 is spaced apart from the driving circuits 130 in the second region AA2. The first type of signal line 140 includes a first segment 141 and a second segment 142 located in the second region AA2 and connected to each other. The first segment 141 is connected to the driving circuits 130 in the first region AA1. The first type of signal line 140 may be used only for transmitting signals to the driving circuits 130 in the first region AA1, meaning the first type of signal line 140 only extends through the second region AA2 but is not used for transmitting signals to the driving circuits 130 in the second region AA2.

In an embodiment, the first segment 141 may be connected to the driving circuits 130 in the second circuit row RC2 within the first region AA1.

In an embodiment, a single first type of signal line 140 is connected to two driving circuits 130 located on both sides of the second region AA2 in the second direction Y in the second circuit row RC2, allowing signals from the second circuit row RC2 on one side of the second region AA2 in the first direction X to be transmitted via the first type of signal line 140 to the driving circuits 130 in the second circuit row RC2 on the other side of the second region AA2 in the first direction X, thereby facilitating control of the operation of the display panel 10.

In an embodiment, the number of first segments 141 in a single first type of signal line 140 may be two. The two first segments 141 may be arranged on both sides of the second segment 142 in the second direction Y. One of the first segments 141 may be used for connection to a driving circuit 130 in the second circuit row RC2 located on one side of the second region AA2 in the second direction Y, and the other first segment 141 may be used for connection to a driving circuit 130 in the second circuit row RC2 located on the other side of the second region AA2 in the second direction Y.

In an embodiment, the first type of signal line 140 may further include a first connection segment 143 located in the first region AA1. The first connection segment 143 may be connected to the driving circuits 130 of the second circuit row RC2. In an embodiment, a single first connection segment 143 may be connected to each driving circuit 130 in the same second circuit row RC2.

In an embodiment, the second type of signal line 150 may further include a second connection segment 153 located in the first region AA1. The second connection segment 153 may be connected to the driving circuits 130 of the third circuit row RC3. In an embodiment, a single second connection segment 153 may be connected to each driving circuit 130 in the same third circuit row RC3.

In an embodiment, there are various ways to set the extension direction of the first segment 141. The first segment 141 may connect the driving circuit 130 in the first region AA1 to the second segment 142 via the shortest path.

By arranging the first segment 141 between adjacent driving circuits 130 in the first direction X within the second region AA2, it is beneficial for the first segment 141 to connect to the driving circuits 130 in the first region AA1 located between adjacent second type signal lines 150 in the first direction X.

In an embodiment, by arranging the first segment 141 between adjacent driving circuits 130 in the first direction X within the second region AA2, it is beneficial for the first segment 141 to connect to the driving circuits 130 in the second circuit row RC2 located between adjacent third circuit rows RC3 in the first direction X.

By setting the minimum spacing between the second segment 142 in the second region AA2 and the driving circuits 130 on one side in the first direction X to be less than the minimum spacing between the second segment 142 and the driving circuits 130 on the other side in the first direction X, the second segment 142, which is not directly connected to the driving circuits 130 in the second region AA2, can be offset toward the driving circuits 130 on one side in the first direction X. This ensures that within the second region AA2, the electric field environment around the first type of signal line 140 can approximate that around the second type of signal line 150, thereby making the operational stability of the first type of signal line 140 similar to that of the second type of signal line 150 during signal transmission, which is beneficial for improving the display uniformity and operational stability of the display panel 10.

In an embodiment, by setting the minimum spacing between the second segment 142 in the second region AA2 and the driving circuits 130 on one side in the first direction X to be less than the minimum spacing between the second segment 142 and the driving circuits 130 on the other side in the first direction X, the second segment 142, which is not directly connected to the driving circuits 130 in the second region AA2, can be offset toward the first circuit row RC1 on one side in the first direction X.

Therefore, when a capacitance (e.g., parasitic capacitance) is formed between the second type of signal line 150 in the second region AA2 and the adjacent first circuit row RC1, the second segment 142 can form a compensation capacitance with the adjacent first circuit row RC1. This compensation capacitance can approximate or equal the capacitance formed between the second type of signal line 150 and the first circuit row RC1.

In one embodiment, when a capacitance (e.g., parasitic capacitance) is formed between the second type of signal line 150 in the second region AA2 and other conductive structures around the adjacent first circuit row RC1, the second segment 142 can form a compensation capacitance with other conductive structures around the adjacent first circuit row RC1. This compensation capacitance can approximate or equal the capacitance formed between the second type of signal line 150 and other conductive structures around the first circuit row RC1. Thus, within the second region AA2, the electric field environment around the first type of signal line 140 can approximate that around the second type of signal line 150, further ensuring that during signal transmission, the operational stability of the first type of signal line 140 is similar to that of the second type of signal line 150, which is beneficial for improving the display uniformity and operational stability of the display panel 10.

In an embodiment, when the operational stability of the first-type signal lines 140 and the second-type signal lines 150 is similar, it may be beneficial to improve the display uniformity and operational stability of the display panel 10. This can refer to the fact that the first-type signal lines 140 may be used to transmit signals to the driving circuits 130 located in odd-numbered rows (e.g., the driving circuits 130 in the second circuit row RC2) within the display panel 10, while the second-type signal lines 150 may be used to transmit signals to the driving circuits 130 located in even-numbered rows (e.g., the driving circuits 130 in the first circuit row RC1 and the third circuit row RC3) within the display panel 10. Therefore, when the operational stability of the first-type signal lines 140 and the second-type signal lines 150 is similar during signal transmission, the operational stability of the driving circuits 130 in odd-numbered rows and the driving circuits 130 in even-numbered rows in the display panel 10 may become similar. Consequently, the operational stability of the light-emitting devices 300 driven by the driving circuits 130 in odd-numbered rows and the operational stability of the light-emitting devices 300 driven by the driving circuits 130 in even-numbered rows may become similar, thereby facilitating the improvement of the display uniformity and operational stability of the display panel 10.

In some embodiments, the first-type signal lines 140 surround at least a portion of the circuit groups CG.

In an embodiment, the first-type signal lines 140 may be located on at least one side of the circuit groups CG in the first direction X, and/or the first-type signal lines 140 may be located on at least one side of the circuit groups CG in the second direction Y, to facilitate the arrangement of the first-type signal lines 140 surrounding at least a portion of the circuit groups CG.

In an embodiment, the second segments 142 may be located on at least one side of the circuit groups CG in the first direction X, and/or the second segments 142 may be located on at least one side of the circuit groups CG in the second direction Y.

In these optional embodiments, by arranging the first-type signal lines 140 to surround at least a portion of the circuit groups CG, the second area AA2 can have larger-sized first-type signal lines 140 adjacent to the circuit groups CG. This facilitates the formation of compensation capacitance between the first-type signal lines 140 and the adjacent first circuit rows RC1, or between the first-type signal lines 140 and other conductive structures around the adjacent first circuit rows RC1, thereby helping to reduce operational differences between the first-type signal lines 140 and the second-type signal lines 150. Moreover, by arranging the first-type signal lines 140 to surround at least a part of the circuit groups CG, the first-type signal lines 140 in the second area AA2 can be better adjacent to the circuit groups CG, which helps improve the structural compactness in the second area AA2, thereby enhancing the light transmittance in the second area AA2.

In some embodiments, the second area AA2 includes an edge area AA2a connected to the first area AA1 and a main area AA2b located on a side of the edge area AA2a away from the first area AA1 in the first direction X. The circuit groups CG include a first circuit group CG1 located in the edge area AA2a and a second circuit group CG2 located in the main area AA2b. The second segments 142 include a first sub-segment 142a disposed around the first circuit group CG1 and a second sub-segment 142b disposed around the second circuit group CG2. The first sub-segment 142a extends from one side of the first circuit group CG1 in the first direction X to a side of the first circuit group CG1 in the second direction Y close to the second circuit group CG2, and/or the second sub-segment 142b extends from one side of the second circuit group CG2 in the second direction Y, passes through one side of the second circuit group CG2 in the first direction X, and extends to the other side of the second circuit group CG2 in the second direction Y.

In an embodiment, the number of first-type signal lines 140 is at least two. Among them, the first segments 141 of at least two first-type signal lines 140 are adjacent in the first direction X, and the first sub-segments 142a are disposed on the same side of the first circuit group CG1 in the first direction X, and/or the first segments 141 of at least two first-type signal lines 140 are adjacent in the first direction X, and the second sub-segments 142b are disposed on both sides of the second circuit group CG2 in the first direction X.

In an embodiment, the number of first circuit groups CG1 located in a single edge area AA2a within the first circuit row RC1 is one, which is beneficial for increasing the size of the main area AA2b in the second area AA2 (e.g., the size of the main area AA2b in the first direction X). This allows the second sub-segments 142b, which surround the circuit groups CG to a large extent in the second area AA2, to have larger dimensions.

In an embodiment, the number of edge areas AA2a is two, and the two edge areas AA2a are disposed on both sides of the main area AA2b in the second direction Y. In an embodiment, the number of first circuit groups CG1 in a single first circuit row RC1 may be two, and the two first circuit groups CG1 may be disposed in the edge areas AA2a on both sides of the main area AA2b.

In an embodiment, the first segments 141 and the first sub-segments 142a may be located in the edge area AA2a, and the second sub-segments 142b may be located in the main area AA2b.

In an embodiment, the second segments 142 further include third sub-segments 142c. Adjacent first sub-segments 142a and second sub-segments 142b in the second direction Y are connected via the third sub-segments 142c, and adjacent second sub-segments 142b in the second direction Y are connected via the third sub-segments 142c.

In an embodiment, there are various ways to set the extension direction of the third sub-segments 142c. The third sub-segments 142c may connect adjacent first sub-segments 142a and second sub-segments 142b in the second direction Y via the shortest path, or the third sub-segments 142c may connect adjacent second sub-segments 142b in the second direction Y via the shortest path. In an embodiment, the third sub-segments 142c may extend along the second direction Y.

In these optional embodiments, by reasonably setting the positions of the first sub-segment 142a and the second sub-segment 142b, the degree to which the first type of signal line 140 surrounds the circuit group CG can be gradually increased as it extends from the edge region AA2a to the main region AA2b. This allows the second region AA2 to have a first type of signal line 140 with a larger size adjacent to the circuit group CG, which is beneficial for reducing the operational differences between the first type of signal line 140 and the second type of signal line 150.

Furthermore, when the number of the first type of signal lines 140 is at least two, by arranging the first segments 141 of at least two first type of signal lines 140 adjacent to each other in the first direction X and arranging the second sub-segments 142b on both sides of the second circuit group CG2 in the first direction X, the structure used to form compensation capacitance within the circuit group CG or the structure used to form compensation capacitance around the circuit group CG (hereinafter referred to as the capacitance structure) can have a smaller size in the first direction X.

In an embodiment, when the second sub-segments 142b of each first type of signal line 140 are all located on the same side of the second circuit group CG2 in the first direction X, to allow each second sub-segment 142b to form a compensation capacitance with the capacitance structure, it is necessary to extend the size of the capacitance structure located on one side of the circuit group CG in the first direction X. By arranging the second sub-segments 142b of at least two first type of signal lines 140 on both sides of the second circuit group CG2 in the first direction X, there is no need to extend the size of the capacitance structure. Instead, smaller-sized capacitance structures located on both sides of the circuit group CG in the first direction X can be used to form compensation capacitances with the second sub-segments 142b of different first type of signal lines 140, thereby effectively reducing the blocking effect of the capacitance structure on light and improving the light transmittance performance in the second region AA2.

In some embodiments of the present application, there are various ways to set the film layer positions of each segment in the first type of signal line 140 and the second type of signal line 150.

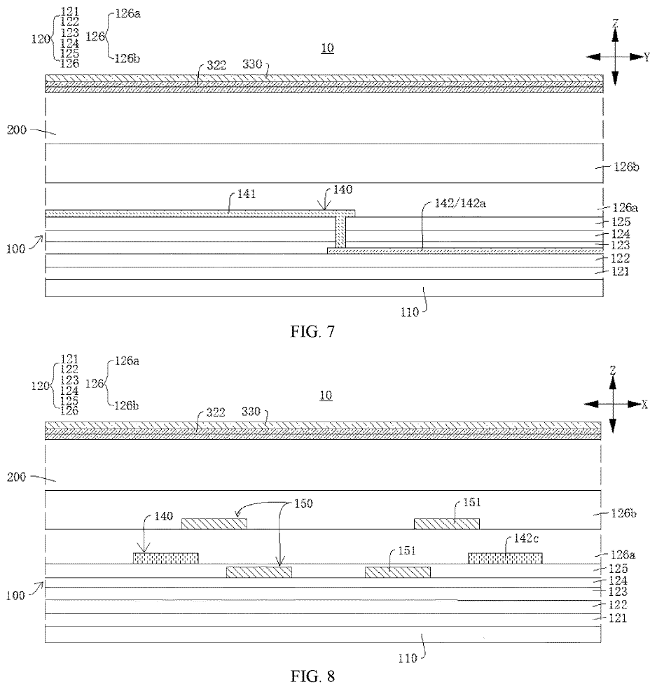

FIG. 6 is a schematic partial cross-sectional view of a display panel 10 according to another embodiment of the present application, FIG. 7 is a schematic partial cross-sectional view of a display panel 10 according to yet another embodiment of the present application, and FIG. 8 is a schematic partial cross-sectional view of a display panel 10 according to still another embodiment of the present application. Here, FIG. 6 may be a schematic partial cross-sectional view of the display panel 10 at position A in FIG. 5, FIG. 7 may be a schematic partial cross-sectional view of the display panel 10 at position B in FIG. 5, and FIG. 8 may be a schematic partial cross-sectional view of the display panel 10 at position C in FIG. 5.

As shown in FIGS. 5 to 8, in some embodiments, one part of the second type of signal line 150 and another part of the second type of signal line 150 are arranged in different layers within the second region AA2, and one part of the first type of signal line 140 and another part of the first type of signal line 140 are arranged in different layers within the second region AA2.

In an embodiment, one part of the first type of signal line 140 and another part of the first type of signal line 140 being arranged in different layers within the second region AA2 may refer to one segment of the first type of signal line 140 and another segment of the first type of signal line 140 being located between different insulating film layers 120.

In an embodiment, one part of the second type of signal line 150 and another part of the second type of signal line 150 being arranged in different layers within the second region AA2 may refer to one segment of the second type of signal line 150 and another segment of the second type of signal line 150 being located between different insulating film layers 120.

In this optional embodiment, by arranging one segment of the second type of signal line 150 and another segment of the second type of signal line 150 in different layers within the second region AA2, one segment of the second type of signal line 150 can be relatively far from the driving circuit 130 to facilitate the arrangement of the second type of signal line 150, while another segment of the second type of signal line 150 can be relatively close to the driving circuit 130 to facilitate the connection between the second type of signal line 150 and the driving circuit 130.

Since one part of the second type of signal line 150 and another part of the second type of signal line 150 are arranged in different layers within the second region AA2, the second type of signal line 150 will change its film layer position within the second region AA2 through vias opened in the insulating film layer 120, and the second type of signal line 150 located within the vias will have a larger resistance. By arranging one part of the first type of signal line 140 and another part of the first type of signal line 140 in different layers within the second region AA2, the first type of signal line 140 can also change its film layer position within the second region AA2 through vias opened in the insulating film layer 120. This allows the resistance of the first type of signal line 140 at the vias within the second region AA2 to serve as a compensation resistance, which can approximate or equal the resistance of the second type of signal line 150 located within the vias. Thus, within the second region AA2, the resistance of the first type of signal line 140 can approximate the resistance of the second type of signal line 150, thereby making the operational stability of the first type of signal line 140 and the second type of signal line 150 similar during signal transmission, which is beneficial for improving the display uniformity and operational stability of the display panel 10.

In some embodiments, the third segment 151 and the fourth segment 152 are arranged in different layers, and the fourth segment 152 is connected to at least one driving circuit 130 within the second region AA2.

In an embodiment, the fourth segment 152 is connected to the driving circuit 130 in the first region AA1 through the third segment 151, and/or adjacent fourth segments 152 in the second direction Y are connected through the third segment 151.

In an embodiment, the fourth segment 152 is located in a film layer closer to the substrate 110 than the third segment 151 within the base plate 100.

In an embodiment, at least a portion of the third segment 151 is disposed in the same layer as the source-drain electrode 131c (in an embodiment, at least a portion of the third segment 151 may be located between the fourth insulating layer 124 and the fifth insulating layer 125), and/or at least a portion of the third segment 151 is located in a film layer on the side of the source-drain electrode 131c away from the substrate 110 within the base plate 100 (in an embodiment, at least a portion of the third segment 151 may be located between the first sub-insulating layer 126a and the second sub-insulating layer 126b), and/or at least a portion of the fourth segment 152 is disposed in the same layer as the gate electrode 131b (in an embodiment, at least a portion of the fourth segment 152 may be located between the second insulating layer 122 and the third insulating layer 123), and/or at least a portion of the fourth segment 152 is located in a film layer between the gate electrode 131b and the source-drain electrode 131c within the base plate 100 (in an embodiment, at least a portion of the fourth segment 152 may be located between the third insulating layer 123 and the fourth insulating layer 124). In these optional embodiments, the fourth segment 152 may be disposed closer to the driving circuit 130 than the third segment 151, facilitating the connection between the fourth segment 152 and the driving circuit 130. The third segment 151 and the fourth segment 152 may be connected through vias formed in the insulating film layer 120.

In some embodiments, there are a plurality of second-type signal lines 150, and the third segments 151 of at least two adjacent second-type signal lines 150 are disposed in different layers, and/or the first-type signal line 140 and the third segment 151 of the second-type signal line 150 located between adjacent driving circuits 130 in the second region AA2 are disposed in different layers. Exemplarily, the third segments 151 of at least two adjacent second-type signal lines 150 corresponding to the same first circuit row RC1 are disposed in different layers, and/or the first-type signal line 140 and the third segment 151 of the second-type signal line 150 located between adjacent circuit groups CG in the same first circuit row RC1 in the second region AA2 are disposed in different layers. In an embodiment, at least two adjacent second-type signal lines 150 corresponding to the same first circuit row RC1 may refer to at least two second-type signal lines 150 being connected to the driving circuits 130 in the same first circuit row RC1.

In an embodiment, the third segments 151 of at least two adjacent second-type signal lines 150 being disposed in different layers may refer to the third segment 151 of one part of the second-type signal lines 150 and the third segment 151 of another adjacent part of the second-type signal lines 150 being located between different insulating film layers 120. Exemplarily, the third segment 151 in one part of the second-type signal lines 150 is located between the fourth insulating layer 124 and the fifth insulating layer 125, and the third segment 151 in another adjacent part of the second-type signal lines 150 is located between the first sub-insulating layer 126a and the second sub-insulating layer 126b. In an embodiment, the first-type signal line 140 and the third segment 151 of the second-type signal line 150 located between adjacent driving circuits 130 in the second region AA2 being disposed in different layers may refer to the first-type signal line 140 (in an embodiment, the third sub-segment 142c) located between adjacent driving circuits 130 in the second region AA2 and the third segment 151 of the second-type signal line 150 being located between different insulating film layers 120.

In an embodiment, the third sub-segment 142c may be located between the fifth insulating layer 125 and the first sub-insulating layer 126a, the third segment 151 in a part of the second-type signal lines 150 is located between the fourth insulating layer 124 and the fifth insulating layer 125, and the third segment 151 in another part of the second-type signal lines 150 is located between the first sub-insulating layer 126a and the second sub-insulating layer 126b. In these optional embodiments, by arranging the third segments 151 of at least two adjacent second-type signal lines 150 in different layers, the third segments 151 of adjacent second-type signal lines 150 can have a smaller spacing in a direction parallel to the plane of the display panel 10, which is beneficial for improving the layout compactness of the second-type signal lines 150. Similarly, by arranging the first-type signal line 140 and the third segment 151 of the second-type signal line 150 located between adjacent driving circuits 130 in the second region AA2 in different layers, the first-type signal line 140 and the third segment 151 of the second-type signal line 150 located between adjacent driving circuits 130 can have a smaller spacing in a direction parallel to the plane of the display panel 10, which is beneficial for improving the layout compactness of the first-type signal line 140 and the second-type signal line 150 between adjacent driving circuits 130.

In an embodiment, since the film layer layout area occupied by the driving circuits 130 in the circuit group CG is relatively large, the fourth segments 152 in each second-type signal line 150 may all be disposed in the same layer to reduce the impact of the fourth segments 152 of each second-type signal line 150 on the layout of the driving circuits 130 in the base plate 100.

In an embodiment, the fourth segments 152 of each second-type signal line 150 corresponding to the same first circuit row RC1 may be spaced apart in the first direction X. The following embodiments are described by taking “the third segment 151 in a part of the second-type signal lines 150 is located between the fourth insulating layer 124 and the fifth insulating layer 125, the third segment 151 in another part of the second-type signal lines 150 is located between the first sub-insulating layer 126a and the second sub-insulating layer 126b, and the fourth segment 152 in the second-type signal lines 150 is located between the second insulating layer 122 and the third insulating layer 123″ as an example. In an embodiment, orthographic projections of the third segments 151 of at least two second-type signal lines 150 on the substrate 110 at least partially overlap, and there may be no gap between the orthographic projections of the third segments 151 of at least two adjacent second-type signal lines 150 on the substrate 110, which can facilitate improving the arrangement density of the second-type signal lines 150, is beneficial for reducing the layout area of the second-type signal lines 150 in the second region AA2, and thus is beneficial for improving the light transmittance in the second region AA2.

In an embodiment, when the third segment 151 extends along the second direction Y, by arranging the orthographic projections of the third segments 151 of at least two second-type signal lines 150 on the substrate 110 to at least partially overlap, it is beneficial to reduce the arrangement dimension of the third segments 151 of each second-type signal line 150 in the first direction X, thereby enhancing the light transmittance in the second area AA2.

In an embodiment, the orthographic projection of the first-type signal line 140 located between adjacent driving circuits 130 in the second area AA2 on the substrate 110 at least partially overlaps with the orthographic projection of the third segment 151 of the second-type signal line 150 on the substrate 110, and there may be no gap between the orthographic projections of at least two adjacent first-type signal lines 140 and the third segments 151 of the second-type signal lines 150 on the substrate 110. This facilitates increasing the arrangement density of the first-type signal lines 140 and the second-type signal lines 150, helps reduce the arrangement area of the first-type signal lines 140 and the second-type signal lines 150 in the second area AA2, and thus enhances the light transmittance in the second area AA2.

In an embodiment, the orthographic projection of the third sub-segment 142c of the first-type signal line 140 in the second area AA2 on the substrate 110 at least partially overlaps with the orthographic projection of the third segment 151 of the second-type signal line 150 on the substrate 110. When both the third sub-segment 142c and the third segment 151 extend along the second direction Y, by arranging the orthographic projection of the third sub-segment 142c of the first-type signal line 140 in the second area AA2 on the substrate 110 to at least partially overlap with the orthographic projection of the third segment 151 of the second-type signal line 150 on the substrate 110, it is beneficial to reduce the arrangement dimensions of the third sub-segment 142c and the third segment 151 in the first direction X, thereby enhancing the light transmittance in the second area AA2.

In some embodiments, the first-type signal line 140 in the second area AA2 and the second-type signal line 150 in the second area AA2 may be at least partially arranged in the same layer. In an embodiment, the first sub-segment 142a may be at least partially arranged in the same layer as the second-type signal line 150. In an embodiment, at least a portion of the first sub-segment 142a may be arranged in the same layer as the fourth segment 152. In an embodiment, the second sub-segment 142b may be at least partially arranged in the same layer as the second-type signal line 150. In an embodiment, at least a portion of the second sub-segment 142b may be arranged in the same layer as the fourth segment 152. In these optional embodiments, by arranging the first-type signal line 140 in the second area AA2 and the second-type signal line 150 in the second area AA2 to be at least partially in the same layer, the material of at least some segments of the first-type signal line 140 in the second area AA2 may be the same as the material of at least some segments of the second-type signal line 150 in the second area AA2. This allows the impedance of the first-type signal line 140 in the second area AA2 and the second-type signal line 150 in the second area AA2 to be similar or identical, which helps reduce operational differences between the first-type signal line 140 and the second-type signal line 150. Moreover, the peripheral electric field environment of the first-type signal line 140 and the second-type signal line 150 arranged in the same layer in the second area AA2 can be similar, making the operational stability of the first-type signal line 140 and the second-type signal line 150 during signal transmission similar. This is beneficial for improving the display uniformity and operational stability of the display panel 10.

In an embodiment, since the fourth segment 152 is relatively close to the driving circuit 130 in the circuit group CG, it is prone to form parasitic capacitance with the driving circuit 130 or structures around the driving circuit 130. Therefore, when both the first sub-segment 142a and the second sub-segment 142b used to form the compensation capacitor are arranged in the same layer as the fourth segment 152, the compensation capacitor formed by the first sub-segment 142a and the second sub-segment 142b can approximate the parasitic capacitance formed by the fourth segment 152. Consequently, the electric field environment around the first-type signal line 140 can approximate that around the second-type signal line 150, making the operational stability of the first-type signal line 140 and the second-type signal line 150 during signal transmission similar. This helps improve the display uniformity and operational stability of the display panel 10. In some embodiments, the first sub-segment 142a and the second sub-segment 142b are at least partially arranged in the same layer.

In an embodiment, the first sub-segment 142a located on one side of the circuit group CG in the first direction X and the second sub-segment 142b located on both sides of the circuit group CG in the first direction X are arranged in the same layer. In these optional embodiments, by arranging the first sub-segment 142a and the second sub-segment 142b to be at least partially in the same layer, the compensation capacitor formed by the first sub-segment 142a of the first-type signal line 140 can approximate the compensation capacitor formed by the second sub-segment 142b. That is, the compensation capacitors formed between the first-type signal line 140 in the second area AA2 and the capacitive structures corresponding to each circuit group CG can be similar. This further enhances the similarity between the electric field environment around the first-type signal line 140 and that around the second-type signal line 150, thereby further reducing operational differences between the first-type signal line 140 and the second-type signal line 150, and further improving the display uniformity and operational stability of the display panel 10.

In some embodiments, the first segment 141 and the first sub-segment 142a are at least partially arranged in different layers, and/or the first segment 141 and the second sub-segment 142b are at least partially arranged in different layers. In an embodiment, the first segment 141 and the first sub-segment 142a being at least partially arranged in different layers may mean that the first segment 141 and at least a portion of the first sub-segment 142a are located between different insulating film layers 120. In an embodiment, the first segment 141 and the second sub-segment 142b being at least partially arranged in different layers may mean that the first segment 141 and at least a portion of the second sub-segment 142b are located between different insulating film layers 120. In an embodiment, the first segment 141 and the third sub-segment 142c are arranged in the same layer, allowing the preparation of the first segment 141 and the third sub-segment 142c to be completed in the same fabrication step, which is beneficial for improving the fabrication efficiency of the display panel 10.

In an embodiment, at least a portion of the first sub-segment 142a is located in a film layer between the first segment 141 and the substrate 110, and/or at least a portion of the second sub-segment 142b is located in a film layer between the first segment 141 and the substrate 110. In an embodiment, at least a portion of the first segment 141 is located in a film layer on a side of the source-drain electrode 131c away from the substrate 110 (in an embodiment, at least a portion of the first segment 141 may be located between the fifth insulating layer 125 and the first sub-insulating layer 126a), and/or at least a portion of the first sub-segment 142a is arranged in the same layer as the gate electrode 131b (in an embodiment, at least a portion of the first sub-segment 142a may be located between the second insulating layer 122 and the third insulating layer 123), and/or at least a portion of the second sub-segment 142b is arranged in the same layer as the gate electrode 131b (in an embodiment, at least a portion of the second sub-segment 142b may be located between the second insulating layer 122 and the third insulating layer 123). In these optional embodiments, by arranging at least a portion of the first segment 141, which does not need to participate in forming the compensation capacitor, and the first sub-segment 142a and/or the second sub-segment 142b in different layers, the first segment 141 does not need to extend into film layers adjacent to the capacitor structure, which is beneficial for the arrangement of the first segment 141.

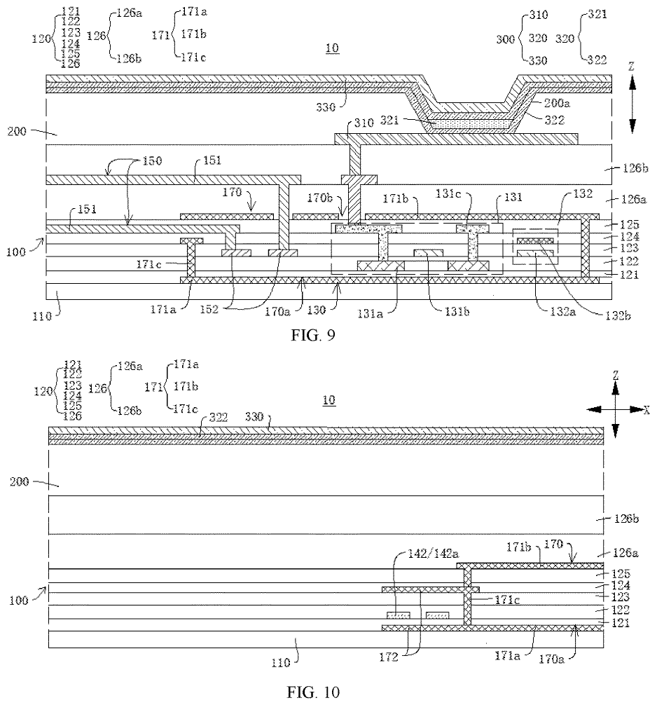

Moreover, since at least a portion of the first segment 141 and the first sub-segment 142a and/or the second sub-segment 142b are arranged in different layers, the first type signal line 140 can achieve changes in film layer position within the second region AA2 through vias formed in the insulating film layer 120, allowing the resistance of the first type signal line 140 at the vias in the second region AA2 to serve as compensation resistance. Consequently, within the second region AA2, the resistance of the first type signal line 140 can approximate that of the second type signal line 150, thereby making the operational stability of the first type signal line 140 and the second type signal line 150 similar during signal transmission, which is beneficial for improving the display uniformity and operational stability of the display panel 10. FIG. 9 is a schematic partial cross-sectional view of a display panel 10 according to another embodiment of the present application.

FIG. 10 is a schematic partial cross-sectional view of a display panel 10 according to yet another embodiment of the present application, and FIG. 11 is a schematic diagram illustrating the positions of a light-shielding structure 170, a driving circuit 130, a first type signal line 140, and a second type signal line 150 according to an embodiment of the present application. For illustrative convenience, the light-shielding structure 170 is indicated by a dashed box in FIG. 11. Here, FIG. 10 may be a partial cross-sectional view of the display panel 10 at position D in FIG. 11. As shown in FIGS. 9 to 11, in some embodiments, the base plate 100 further includes a light-shielding structure 170 disposed on one side of the substrate 110. The light-shielding structure 170 encloses to form a light-shielding space 170a, and the driving circuit 130 is located within the light-shielding space 170a.

In an embodiment, the light-shielding structure 170 may be located only within the second region AA2, meaning the light-shielding structure 170 may only be used to accommodate the driving circuit 130 in the second region AA2, which is beneficial for increasing the pixel arrangement density in the first region AA1 and improving the display effect of the first region AA1. In an embodiment, the light-shielding structure 170 may include a light-shielding main body 171, which encloses to form the light-shielding space 170a. In an embodiment, the light-shielding main body 171 may include a first light-shielding portion 171a, a second light-shielding portion 171b disposed on a side of the first light-shielding portion 171a away from the substrate 110, and a third light-shielding portion 171c disposed between the first light-shielding portion 171a and the second light-shielding portion 171b. A surface of the first light-shielding portion 171a facing the light-shielding space 170a may serve as a bottom wall surface of the light-shielding space 170a, a surface of the second light-shielding portion 171b facing the light-shielding space 170a may serve as a top wall surface of the light-shielding space 170a, and the third light-shielding portion 171c may be annular, with a surface of the third light-shielding portion 171c facing the light-shielding space 170a serving as a side wall surface of the light-shielding space 170a.

In an embodiment, the material of the light-shielding structure 170 may include a light-shielding material. In an embodiment, the material of the light-shielding structure 170 may include at least one of a reflective material and an absorptive material. In an embodiment, the material of the light-shielding structure 170 may include an opaque metal material. In an embodiment, there are various ways to set the position of the light-shielding structure 170 within the base plate 100, and the position of the light-shielding structure 170 can be set according to the convenience of accommodating the driving circuit 130.

In an embodiment, the first light-shielding portion 171a may be located between the substrate 110 and the first insulating layer 121, the second light-shielding portion 171b may be located between the fifth insulating layer 125 and the first sub-insulating layer 126a, and the third light-shielding portion 171c may penetrate through at least one of the first insulating layer 121, the second insulating layer 122, the third insulating layer 123, the fourth insulating layer 124, and the fifth insulating layer 125, enabling the light-shielding space 170a formed by the light-shielding structure 170 to better accommodate the driving circuit 130.

In an embodiment, the circuit group CG may be located within the light-shielding space 170a. In an embodiment, a single light-shielding structure 170 may correspond to a single circuit group CG, meaning one light-shielding space 170a may accommodate one circuit group CG, and different circuit groups CG may be located in different light-shielding spaces 170a. In an embodiment, the light-shielding structure 170 is provided with a communication opening 170b, and the second type signal line 150 extends from outside the light-shielding space 170a into the light-shielding space 170a via the communication opening 170b. In an embodiment, the driving circuit 130 and the fourth segment 152 may be located within the light-shielding space 170a, and the third segment 151 extends from outside the light-shielding space 170a into the light-shielding space 170a via the communication opening 170b.

In an embodiment, when the third segment 151 of the second type of signal line 150 is located between the fourth insulating layer 124 and the fifth insulating layer 125, the connection opening 170b may be at least partially formed in the third light-shielding portion 171c, and the third segment 151 of the second type of signal line 150 located between the fourth insulating layer 124 and the fifth insulating layer 125 can extend into the light-shielding space 170a through the connection opening 170b formed in the third light-shielding portion 171c. When the third segment 151 of the second type of signal line 150 is located between the first sub-insulating layer 126a and the second sub-insulating layer 126b, the connection opening 170b may be at least partially formed in the second light-shielding portion 171b, and the third segment 151 of the second type of signal line 150 located between the first sub-insulating layer 126a and the second sub-insulating layer 126b can extend into the light-shielding space 170a through the connection opening 170b formed in the second light-shielding portion 171b.

In an embodiment, the transistor 131 in the driving circuit 130 may also be connected to the light-emitting device 300 through the connection opening 170b. In an embodiment, the second light-emitting control transistor 131 in the driving circuit 130 may be connected to the first electrode 310 of the light-emitting device 300 through the connection opening 170b formed in the second light-shielding portion 171b.

In an embodiment, since the first type of signal line 140 may not need to be connected to the driving circuit 130 in the second region AA2, the first type of signal line 140 may be arranged outside the light-shielding space 170a to reduce the occupation of the light-shielding space 170a by the first type of signal line 140, thereby facilitating the arrangement of the driving circuit 130 within the light-shielding space 170a.

In these optional embodiments, since the display panel 10 in the second region AA2 has good light transmittance, by arranging the light-shielding structure 170 for blocking light in the second region AA2 and placing the driving circuit 130 in the second region AA2 within the light-shielding space 170a, it is beneficial to reduce the impact of light on the operational stability of the driving circuit 130. In an embodiment, the light-shielding structure 170 may be used to limit light from illuminating the semiconductor structure 131a of the transistor 131 in the driving circuit 130, and the transistor 131 can have good operational stability, thereby helping to improve the operational stability of the display panel 10.

In an embodiment, the display panel 10 may include a fixed voltage terminal, and the light-shielding structure 170 may be electrically connected to the fixed voltage terminal, and the light-shielding structure 170 can have a fixed voltage, ensuring good potential stability for the light-shielding structure 170. In an embodiment, the fixed voltage terminal may be used to transmit a first power supply voltage signal, a second power supply voltage signal, or a reset signal. Further, the light-shielding structure 170 may be electrically connected to the fixed voltage terminal through the first power supply voltage signal line ELVDD, the second power supply voltage signal line ELVSS, the first reset signal line VREF1, or the second reset signal line VREF2.

In some embodiments, at least a portion of the light-shielding structure 170 may serve as the capacitor structure described in the previous embodiments, meaning that a compensation capacitor may be formed between the adjacent first type of signal line 140 and the light-shielding structure 170.

In an embodiment, a compensation capacitor may be formed between the adjacent second segment 142 and the light-shielding structure 170. Further, a compensation capacitor may be formed between the adjacent first sub-segment 142a and the light-shielding structure 170, and/or between the adjacent second sub-segment 142b and the light-shielding structure 170.

In an embodiment, the minimum spacing between the second segment 142 and the light-shielding structure 170 on one side in the first direction X is less than the minimum spacing between the second segment 142 and the light-shielding structure 170 on the other side in the first direction X, allowing the second segment 142, which is not directly connected to the driving circuit 130 in the second region AA2, to shift toward the light-shielding structure 170 on one side in the first direction X. This facilitates the formation of a compensation capacitor between the second segment 142 and its adjacent light-shielding structure 170. The compensation capacitor may approximate or equal the capacitance formed between the second type of signal line 150 and other conductive structures around the first circuit row RC1, and in the second region AA2, the electric field environment around the first type of signal line 140 can approximate that around the second type of signal line 150. This ensures that during signal transmission, the operational stability of the first type of signal line 140 is similar to that of the second type of signal line 150, which helps improve the display uniformity and operational stability of the display panel 10.

In an embodiment, the minimum spacing between the second segment 142 and the adjacent light-shielding structure 170 is not greater than 6 micrometers, to facilitate the formation of a compensation capacitor between the adjacent second segment 142 and the light-shielding structure 170. In an embodiment, the minimum spacing between the second segment 142 and the adjacent light-shielding structure 170 is not greater than 3 micrometers.

In an embodiment, the minimum spacing between the first sub-segment 142a and the light-shielding structure 170 on one side in the first direction X is less than the minimum spacing between the first sub-segment 142a and the light-shielding structure 170 on the other side in the first direction X, and/or the minimum spacing between the second sub-segment 142b and the light-shielding structure 170 on one side in the first direction X is less than the minimum spacing between the second sub-segment 142b and the light-shielding structure 170 on the other side in the first direction X.

In an embodiment, the spacing between the first sub-segment 142a and the light-shielding structure 170 may not be greater than 6 micrometers, and/or the spacing between the second sub-segment 142b and the light-shielding structure 170 may not be greater than 6 micrometers. In an embodiment, the spacing between the first sub-segment 142a and the light-shielding structure 170 may not be greater than 3 micrometers, and/or the spacing between the second sub-segment 142b and the light-shielding structure 170 may not be greater than 3 micrometers.

In an embodiment, the orthographic projection of the first type of signal line 140 on the substrate 110 partially overlaps with the orthographic projection of the light-shielding structure 170 on the substrate 110, and a compensation capacitor can be formed between the adjacent first type of signal line 140 and the light-shielding structure 170. In an embodiment, the orthographic projection of the second segment 142 on the substrate 110 partially overlaps with the orthographic projection of the light-shielding structure 170 on the substrate 110. Further in an embodiment, the orthographic projection of the first sub-segment 142a on the substrate 110 partially overlaps with the orthographic projection of the light-shielding structure 170 on the substrate 110, and/or the orthographic projection of the second sub-segment 142b on the substrate 110 partially overlaps with the orthographic projection of the light-shielding structure 170 on the substrate 110.

In some embodiments, the light-shielding structure 170 includes a protruding structure 172 disposed on a side of the light-shielding main body 171 away from the light-shielding space 170a, and the orthographic projection of the first type of signal line 140 on the substrate 110 partially overlaps with the orthographic projection of the protruding structure 172 on the substrate 110.

In an embodiment, the orthographic projection of the second segment 142 on the substrate 110 partially overlaps with the orthographic projection of the protruding structure 172 on the substrate 110. Further in an embodiment, the orthographic projection of the first sub-segment 142a on the substrate 110 partially overlaps with the orthographic projection of the protruding structure 172 on the substrate 110, and/or the orthographic projection of the second sub-segment 142b on the substrate 110 partially overlaps with the orthographic projection of the protruding structure 172 on the substrate 110.

In an embodiment, a compensation capacitor is formed between the adjacent second segment 142 and the protruding structure 172.

In an embodiment, at least a portion of the second segment 142 is disposed in the same layer as the gate electrode 131b (in an embodiment, at least a portion of the second segment 142 may be located between the second insulating layer 122 and the third insulating layer 123), and/or at least a portion of the protruding structure 172 is located in a film layer between the semiconductor structure 131a in the base plate 100 and the substrate 110 (in an embodiment, at least a portion of the protruding structure 172 may be located between the substrate 110 and the first insulating layer 121), and/or at least a portion of the protruding structure 172 is located in a film layer between the gate electrode 131b and the source-drain electrode 131c in the base plate 100 (in an embodiment, at least a portion of the protruding structure 172 may be located between the third insulating layer 123 and the fourth insulating layer 124).

In an embodiment, the protruding structure may be disposed around the light-shielding main body 171. In an embodiment, a portion of the protruding structure may be located on both sides of the light-shielding main body 171 in the first direction X, and another portion of the protruding structure may be located on both sides of the light-shielding main body 171 in the second direction Y.

In an embodiment, the size of the compensation capacitor can be controlled by controlling the overlapping area between the orthographic projection of the first type of signal line 140 on the substrate 110 and the orthographic projection of the protruding structure 172 on the substrate 110.

As an example, as shown in FIG. 11, the orthographic projection of the second segment 142 on the substrate 110 may only partially overlap with the orthographic projection of the protruding structure located on at least one side of the light-shielding main body 171 in the first direction X on the substrate 110, that is, the formed compensation capacitor may only be located on at least one side of the third light-shielding portion 171c in the first direction X. In an embodiment, the orthographic projection of the first sub-segment 142a on the substrate 110 may only partially overlap with the orthographic projection of the protruding structure located on one side of the light-shielding main body 171 in the first direction X on the substrate 110, and the orthographic projections of the second sub-segments 142b of two adjacent first type of signal lines 140 on the substrate 110 may only partially overlap with the orthographic projections of the protruding structures located on both sides of the light-shielding main body 171 in the first direction X on the substrate 110, respectively.

In another embodiment, the orthographic projection of the second segment 142 on the substrate 110 may partially overlap with the orthographic projection of the protruding structure located on at least one side of the light-shielding main body 171 in the first direction X on the substrate 110, and the orthographic projection of the second segment 142 on the substrate 110 may partially overlap with the orthographic projection of the protruding structure located on at least one side of the light-shielding main body 171 in the second direction Y on the substrate 110 (not shown in the figure), that is, a portion of the formed compensation capacitor may be located on at least one side of the third light-shielding portion 171c in the first direction X, and another portion of the formed compensation capacitor may be located on at least one side of the third light-shielding portion 171c in the second direction Y.

In an embodiment, the orthographic projection of the first sub-segment 142a on the substrate 110 may partially overlap with the orthographic projection of the protruding structure located on one side of the light-shielding main body 171 in the first direction X on the substrate 110, and the orthographic projection of the first sub-segment 142a on the substrate 110 may partially overlap with the orthographic projection of the protruding structure located on one side of the light-shielding main body 171 in the second direction Y on the substrate 110; the orthographic projections of the second sub-segments 142b of two adjacent first type of signal lines 140 on the substrate 110 may partially overlap with the orthographic projections of the protruding structures located on both sides of the light-shielding main body 171 in the first direction X on the substrate 110, respectively, and the orthographic projection of the second sub-segment 142b on the substrate 110 may partially overlap with the orthographic projection of the protruding structure located on one side of the light-shielding main body 171 in the second direction Y on the substrate 110.

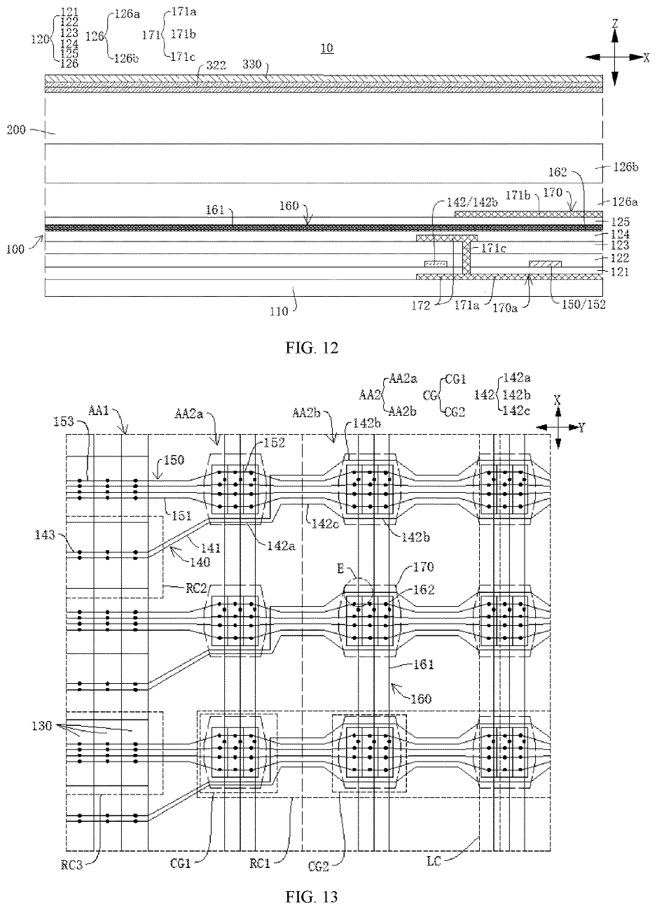

FIG. 12 is a schematic partial cross-sectional view of a display panel 10 according to another embodiment of the present application, and FIG. 13 is a schematic diagram showing positions of a light-shielding structure 170, a driving circuit 130, a first type of signal line 140, a second type of signal line 150, and a third type of signal line 160 according to an embodiment of the present application. Herein, FIG. 12 may be a schematic partial cross-sectional view of the display panel 10 at position E in FIG. 13.

As shown in FIG. 12 and FIG. 13, in some embodiments, the display panel 10 further includes a circuit column LC, the circuit column LC includes driving circuits 130 located in the same column in the first direction X within the first area AA1, the base plate 100 further includes a third type of signal line 160, a single third type of signal line 160 is connected to two driving circuits 130 located on both sides of the second area AA2 in the first direction X in the circuit column LC, and the third type of signal line 160 is connected to at least one driving circuit 130 in the circuit column LC.

In an embodiment, the number of the third type of signal lines 160 may be at least two, and the at least two third type of signal lines 160 may be arranged at intervals in the second direction Y.

In this optional embodiment, the third type of signal line 160 may be used to provide signals to the driving circuits 130 located in the same column in the first direction X within the first region AA1, thereby facilitating the operation of the driving circuits 130. In an embodiment, the third type of signal line 160 may be used to transmit data signals, meaning the third type of signal line 160 may be multiplexed as the data signal line Vdata in the above embodiments. In some embodiments, the third type of signal line 160 includes a fifth segment 161 and a sixth segment 162 connected to each other. The orthographic projection of the fifth segment 161 on the substrate 110 partially overlaps with the orthographic projection of the first type of signal line 140 on the substrate 110. The sixth segment 162 is connected to at least one driving circuit 130 in the second region AA2, and the orthographic projection of the sixth segment 162 on the substrate 110 partially overlaps with the orthographic projection of the second type of signal line 150 on the substrate 110. Here, the fifth segment 161 and the first type of signal line 140 are at least partially arranged in different layers, and the sixth segment 162 and the second type of signal line 150 are at least partially arranged in different layers.

In an embodiment, the fifth segment 161 may extend from outside the light-shielding structure 170 to inside the light-shielding structure 170 through a connection opening 170b, and the sixth segment 162 may be located within the light-shielding space 170a. In an embodiment, the sixth segment 162 is connected to the driving circuits 130 in the first region AA1 via the fifth segment 161, and/or adjacent sixth segments 162 in the first direction X are connected via the fifth segment 161. In an embodiment, at least a portion of the fifth segment 161 is arranged in the same layer as the source-drain electrode 131c (in an embodiment, at least a portion of the fifth segment 161 may be located between the fourth insulating layer 124 and the fifth insulating layer 125), and/or at least a portion of the fifth segment 161 is located in a film layer on the side of the source-drain electrode 131c in the base plate 100 facing away from the substrate 110 (in an embodiment, at least a portion of the fifth segment 161 may be located between the first sub-insulating layer 126a and the second sub-insulating layer 126b). In an embodiment, at least a portion of the sixth segment 162 is arranged in the same layer as the source-drain electrode 131c (in an embodiment, at least a portion of the sixth segment 162 may be located between the fourth insulating layer 124 and the fifth insulating layer 125). In these optional embodiments, by reasonably setting the relative positional relationship between the third type of signal line 160 and the first type of signal line 140 and the second type of signal line 150, it is beneficial to reduce the interference of the arrangement of the third type of signal line 160 on the arrangement of the first type of signal line 140 and the second type of signal line 150. Please refer to FIGS. 1 to 13.

An embodiment of the first aspect of the present application further provides a display panel 10, which has a first region AA1 and a second region AA2. The display panel 10 includes: a base plate 100, including a substrate 110, and driving circuits 130, a first type of signal line 140, and a second type of signal line 150 arranged on the same side of the substrate 110; a light-emitting device 300, arranged on one side of the base plate 100, with the driving circuits 130 connected to the light-emitting device 300. Here, both the first region AA1 and the second region AA2 are provided with driving circuits 130 and light-emitting devices 300. The first type of signal line 140 and the second type of signal line 150 are at least partially arranged in the second region AA2. The first type of signal line 140 is spaced apart from the driving circuits 130 in the second region AA2. The second type of signal line 150 is connected to at least one driving circuit 130 in the second region AA2. One part of the second type of signal line 150 and another part of the second type of signal line 150 are arranged in different layers within the second region AA2, and one part of the first type of signal line 140 and another part of the second type of signal line 150 are arranged in different layers within the second region AA2.

In a display panel 10 provided by an embodiment of the present application, the display panel 10 includes a base plate 100 and a light-emitting device 300. The light-emitting device 300 is arranged on one side of the base plate 100. The base plate 100 includes a substrate 110, and driving circuits 130, a first type of signal line 140, and a second type of signal line 150 arranged on the same side of the substrate 110. The driving circuits 130 are connected to the light-emitting device 300, enabling the driving circuits 130 to drive the light-emitting display of the light-emitting device 300. The display panel 10 has a first region AA1 and a second region AA2. Both the first region AA1 and the second region AA2 are provided with driving circuits 130 and light-emitting devices 300, allowing both the first region AA1 and the second region AA2 to be used for light-emitting display. Both the first type of signal line 140 and the second type of signal line 150 can be used to connect to the driving circuits 130 and provide signals to the driving circuits 130, thereby facilitating the operation of the driving circuits 130. The first type of signal line 140 and the second type of signal line 150 are at least partially arranged in the second region AA2. The second type of signal line 150 is connected to at least one driving circuit 130 in the second region AA2, enabling the second type of signal line 150 to transmit signals to the driving circuits 130 in the second region AA2.

The first type of signal line 140 is spaced apart from the driving circuits 130 in the second region AA2, meaning the first type of signal line 140 may only extend through the second region AA2 but is not used to transmit signals to the driving circuits 130 in the second region AA2. By arranging one part of the second type of signal line 150 and another part of the second type of signal line 150 in different layers within the second region AA2, one segment of the second type of signal line 150 can be relatively far from the driving circuits 130 to facilitate the arrangement of the second type of signal line 150, and another segment of the second type of signal line 150 can be relatively close to the driving circuits 130 to facilitate the connection between the second type of signal line 150 and the driving circuits 130.

Since a part of the second-type signal line 150 and another part of the second-type signal lines 150 are arranged in different layer within the second area AA2, the second-type signal lines 150 achieve changes in layer position through vias in the second area AA2, and the second-type signal lines 150 located within the vias exhibit relatively high resistance. By arranging a part of the first-type signal line 140 and another part of the first-type signal line 140 in different layers within the second area AA2, the first-type signal lines 140 can also achieve changes in layer position through vias in the second area AA2. This allows the resistance of the first-type signal lines 140 at the vias in the second area AA2 to serve as compensation resistance, which can approximate or equal the resistance of the second-type signal lines 150 located within the vias. Consequently, within the second area AA2, the resistance of the first-type signal lines 140 can approximate that of the second-type signal lines 150, thereby making the operational stability of the first-type signal lines 140 and the second-type signal lines 150 similar during signal transmission, which is beneficial for improving the display uniformity and operational stability of the display panel 10.

In an embodiment, a display panel 10 provided by an embodiment of the first aspect of the present application may be the display panel 10 in any of the preceding embodiments. Therefore, the display panel 10 provided by the embodiment of the present application may have the structure and beneficial effects of the display panel 10 in any of the preceding embodiments, and no further elaboration is provided herein.

Please refer to FIGS. 1 to 13. An embodiment of the first aspect of the present application further provides a display panel 10, which includes a first area AA1 and a second area AA2. The display panel 10 includes: a base plate 100 including a substrate 110, a driving circuit 130, first-type signal lines 140, and second-type signal lines 150 disposed on the same side of the substrate 110; a light-shielding structure 170 disposed on one side of the substrate 110, and the light-shielding structure 170 encloses to form a light-shielding space 170a, and the driving circuit 130 is located within the light-shielding space 170a; and a light-emitting device 300 disposed on one side of the base plate 100, and the driving circuit 130 is connected to the light-emitting device 300. The driving circuit 130 and the light-emitting device 300 are disposed in both the first area AA1 and the second area AA2. At least a part of the first-type signal lines 140 and the second-type signal lines 150 are disposed in the second area AA2. The first-type signal lines 140 are spaced apart from the driving circuit 130 in the second area AA2 and are located outside the light-shielding space 170a. The light-shielding structure 170 is provided with a communication opening 170b, and the second-type signal lines 150 extend from outside the light-shielding space 170a into the light-shielding space 170a through the communication opening 170b. The second-type signal lines 150 are connected to at least one driving circuit 130 in the second area AA2. The first-type signal lines 140 include a first segment 141 and a second segment 142 that are located in the second area AA2 and connected to each other. The first segment 141 is connected to the driving circuit 130 in the first area AA1 and is located between adjacent light-shielding structures 170 in the first direction X within the second area AA2. The minimum spacing between the second segment 142 and the light-shielding structure 170 on one side in the first direction X is less than the minimum spacing between the second segment 142 and the light-shielding structure 170 on the other side in the first direction X, and a compensation capacitor is formed between the adjacent second segment 142 and the light-shielding structure 170.

In the display panel 10 provided by the embodiment of the present application, the display panel 10 includes a base plate 100, a light-shielding structure 170, and a light-emitting device 300. The light-emitting device 300 is disposed on one side of the base plate 100. The base plate 100 includes a substrate 110, a driving circuit 130, first-type signal lines 140, and second-type signal lines 150 disposed on the same side of the substrate 110. The driving circuit 130 is connected to the light-emitting device 300, enabling the driving circuit 130 to drive the light-emitting device 300 for light-emitting display. The display panel 10 has a first area AA1 and a second area AA2, both of which are provided with the driving circuit 130 and the light-emitting device 300, allowing both the first area AA1 and the second area AA2 to be used for light-emitting display.

The light-shielding structure 170 is disposed on one side of the substrate 110 and encloses to form a light-shielding space 170a. The driving circuit 130 is located within the light-shielding space 170a, which helps reduce the impact of light on the operational stability of the driving circuit 130. In an embodiment, the light-shielding structure 170 can be used to limit light from illuminating the semiconductor structure 131a of the transistor 131 in the driving circuit 130, enabling the transistor 131 to exhibit better operational stability, thereby contributing to improved operational stability of the display panel 10.

Both the first-type signal lines 140 and the second-type signal lines 150 can be used to connect to the driving circuit 130 and provide signals to the driving circuit 130, facilitating the operation of the driving circuit 130. At least a part of the first-type signal line 140 and the second-type signal line 150 are disposed in the second area AA2. The light-shielding structure 170 is provided with a communication opening 170b, and the second-type signal lines 150 extend from outside the light-shielding space 170a into the light-shielding space 170a through the communication opening 170b. The second-type signal lines 150 are connected to at least one driving circuit 130 in the second area AA2, enabling the second-type signal lines 150 to transmit signals to the driving circuit 130 in the second area AA2.

The first type of signal lines 140 are arranged at intervals from the driving circuits 130 in the second area AA2, and the first type of signal lines 140 are located outside the light-shielding spaces 170a. The first type of signal lines 140 include a first segment 141 and a second segment 142 that are located in the second area AA2 and connected to each other. The first segment 141 is connected to the driving circuits 130 in the first area AA1. The first type of signal lines 140 may be used only for transmitting signals to the driving circuits 130 in the first area AA1, that is, the first type of signal lines 140 only extend through the second area AA2 but are not used for transmitting signals to the driving circuits 130 in the second area AA2. By arranging the first segment 141 between adjacent light-shielding structures 170 in the first direction X within the second area AA2, it is beneficial for the first segment 141 to connect with the driving circuits 130 in the first area AA1 located between adjacent second type of signal lines 150 in the first direction X. By setting the minimum spacing between the second segment 142 and the light-shielding structure 170 on one side in the first direction X to be smaller than the minimum spacing between the second segment 142 and the light-shielding structure 170 on the other side in the first direction X, the second segment 142, which is not directly connected to the driving circuits 130 in the second area AA2, can be offset toward the light-shielding structure 170 on one side in the first direction X. This facilitates the formation of a compensation capacitor between the second segment 142 and its adjacent light-shielding structure 170. The compensation capacitor can approximate or equal the capacitance formed between the second type of signal lines 150 and other conductive structures in the second area AA2. As a result, within the second area AA2, the electric field environment around the first type of signal lines 140 can approximate that around the second type of signal lines 150. This ensures that during signal transmission, the operational stability of the first type of signal lines 140 approximates that of the second type of signal lines 150, which is beneficial for improving the display uniformity and operational stability of the display panel 10.

In an embodiment, a display panel 10 provided by an embodiment of the first aspect of the present application may be the display panel 10 in any of the preceding embodiments. Therefore, the display panel 10 provided by the embodiment of the present application may have the structure and beneficial effects of the display panel 10 in any of the preceding embodiments, and no further elaboration is provided herein.

An embodiment of the second aspect of the present application provides a display device, which includes the display panel 10 according to any of the preceding embodiments. Since the display device provided by the embodiment of the second aspect of the present application includes the display panel 10 according to any embodiment of the first aspect, the display device provided by the embodiment of the second aspect of the present application has the beneficial effects of the display panel 10 according to any embodiment of the first aspect, and no further elaboration is provided herein.

The display device in the embodiments of the present application includes, but is not limited to, mobile phones, personal digital assistants (PDAs), tablet computers, e-books, televisions, access control systems, smart landline phones, consoles, and other devices with display functions. The technical features of the above embodiments may be combined arbitrarily. For the sake of brevity, not all possible combinations of the technical features in the above embodiments are described. However, as long as there is no contradiction in the combination of these technical features, they should be considered within the scope of this specification. The above embodiments only express several implementations of the present disclosure, and the description is relatively specific and detailed, but should not be construed as limiting the scope of the patent. Those of ordinary skill in the art may make several modifications and improvements without departing from the concept of the present disclosure, and these all fall within the protection scope of the present disclosure. Therefore, the protection scope of the patent of the present disclosure shall be subject to the appended claims.

1. A display panel, comprising a first region and a second region, the display panel comprising:
a base plate, comprising a substrate, a plurality of driving circuits, first type of signal lines and second type of signal lines disposed on a same side of the substrate;
at least one light-emitting device disposed on a side of the base plate, the driving circuit being connected to the at least one light-emitting device,
wherein the driving circuit and the at least one light-emitting device are respectively disposed in both the first region and the second region, at least a part of the first type of signal lines and the second type of signal lines are disposed in the second region,
the first type of signal line is spaced apart from the driving circuit in the second region, the second type of signal line is connected to at least one of the driving circuits in the second region,
the first type of signal line comprises a first segment and a second segment located in the second region and connected to each other, the first segment is connected to the driving circuit in the first region, and the first segment is located between the driving circuits adjacent in a first direction within the second region,
a minimum distance between the second segment and the driving circuit on one side in the first direction is less than a minimum distance between the second segment and another driving circuit on another side in the first direction.

2. The display panel according to claim 1, wherein the display panel comprises a plurality of circuit groups located in the second region, the plurality of circuit groups are arrayed in the first direction and a second direction, the first type of signal line is disposed surrounding at least a portion of the circuit groups, wherein the first direction intersects the second direction;
at least one of the second type of signal lines is connected to at least two circuit groups adjacent in the second direction;
each of the circuit groups corresponds to a repeated pixel unit group, the repeated pixel unit group comprises a plurality of the light-emitting devices, the circuit group comprises a plurality of the driving circuits correspondingly disposed with the light-emitting devices.

3. The display panel according to claim 2, wherein
the second region comprises two edge regions adjoining the first region and a main region located on a side of the edge regions away from the first region in the first direction, the two edge regions are disposed on two sides of the main region in the second direction, the circuit groups comprise first circuit groups located in the edge regions and second circuit groups located in the main region, the second segment comprises first sub-segments disposed around peripheries of the first circuit groups and second sub-segments disposed around peripheries of the second circuit groups,
wherein the first sub-segment extends from one side of the first circuit group in the first direction to a side of the first circuit group in the second direction close to the second circuit group, the second sub-segment extends from one side of the second circuit group in the second direction, via one side of the second circuit group in the first direction, to another side of the second circuit group in the second direction.

4. The display panel according to claim 3, wherein
one of the circuit groups comprises one driving circuit connected to one light-emitting device emitting red light, one driving circuit connected to one light-emitting device emitting green light, and one driving circuit connected to one light-emitting device emitting blue light,
the display panel comprises a first circuit row located in the second region, the first circuit row comprises the circuit groups located in a same row in the second direction, a number of the first circuit groups located in a single edge region within the first circuit row is one;
wherein first segments of at least two first type of signal lines are adjacent in the first direction and the first sub-segments are disposed on a same side of the first circuit groups in the first direction,
first segments of at least two first type of signal lines are adjacent in the first direction and the second sub-segments are disposed on two sides of the second circuit groups in the first direction.

5. The display panel according to claim 4, wherein the first sub-segment and the second sub-segment are at least partially disposed in a same layer;
the first segment and the first sub-segment are at least partially disposed in different layers, the first segment and the second sub-segment are at least partially disposed in different layers;
at least a portion of the first sub-segment is located in a film layer between the first segment and the substrate, at least a portion of the second sub-segment is located in a film layer between the first segment and the substrate;
the driving circuit comprises a transistor, the transistor comprises a semiconductor structure, a gate located on a side of the semiconductor structure away from the substrate, and a source/drain located on a side of the gate away from the substrate, at least a portion of the first segment is located in a film layer on a side of the source-drain away from the substrate, at least a portion of the first sub-segment is disposed in a same layer as the gate, at least a portion of the second sub-segment is disposed in a same layer as the gate; the second segment further comprises a third sub-segment, the first sub-segment and the second sub-segment adjacent in the second direction are connected via the third sub-segment, and the second sub-segments adjacent in the second direction are connected via the third sub-segment;
the first segment and the third sub-segment are disposed in a same layer.

6. The display panel according to claim 1, wherein the display panel further comprises a second circuit row and a third circuit row arranged in two rows,
the second circuit row comprises a part of the driving circuits located in a same row in the second direction within the first region, the third circuit row comprises another part of the driving circuits located in a same row in the second direction within the first region,
a first type of signal line is connected to two driving circuits located on two sides of the second region in the second direction within the second circuit row, a second type of signal line is connected to two driving circuits located on two sides of the second region in the second direction within the third circuit row, wherein the first direction intersects the second direction;
the second circuit row and the third circuit row are alternately arranged in the first direction.

7. The display panel according to claim 1, wherein the base plate further comprises a light-shielding structure disposed on a side of the substrate, the light-shielding structure is formed with a light-shielding space, and the driving circuit is located within the light-shielding space;
the light-shielding structure is provided with a communication opening, and the second type of signal line extends from outside the light-shielding space into the light-shielding space via the communication opening.

8. The display panel according to claim 7, wherein the first type of signal line is located outside the light-shielding space; a minimum spacing between the second segment and the light-shielding structure on one side in the first direction is less than a minimum spacing between the second segment and the light-shielding structure on the other side in the first direction;
a compensation capacitor is formed between an adjacent second segment and the light-shielding structure;
an orthographic projection of the first type of signal line on the substrate partially overlaps with an orthographic projection of the light-shielding structure on the substrate;
the light-shielding structure comprises a light-shielding main body and a protruding structure disposed on a side of the light-shielding main body away from the light-shielding space, and an orthographic projection of the first type of signal line on the substrate partially overlaps with an orthographic projection of the protruding structure on the substrate;
the second segment and the protruding structure adjacent to the second segment has a compensation capacitor formed therebetween;
the driving circuit comprises a transistor, the transistor comprise a semiconductor structure, a gate located on a side of the semiconductor structure away from the substrate, and a source-drain located on a side of the gate away from the substrate, at least a portion of the second segment is disposed in the same layer as the gate, at least a portion of the protruding structure is located in a film layer between the semiconductor structure and the substrate within the base plate, at least a portion of the protruding structure is located in a film layer between the gate and the source-drain within the base plate;
the display panel comprises a circuit group located within the second region, a single circuit group comprises at least two driving circuits, and the circuit group is located within the light-shielding space.

9. The display panel according to claim 1, wherein a part of the second type of signal line and another part of the second type of signal line are disposed in different layers within the second region, and a part of the first type of signal line and another part of the first type of signal line are disposed in different layers within the second region; the first type of signal lines within the second region and the second type of signal lines within the second region are at least partially disposed in the same layer.

10. The display panel according to claim 9, wherein the second type of signal line comprises a third segment and a fourth segment located in the second region and connected to each other, the third segment and the fourth segment are disposed in different layers, and the fourth segment is connected to at least one driving circuit within the second region;
the fourth segment is connected to the driving circuit within the first region via the third segment, adjacent fourth segments in the second direction are connected via the third segment, wherein the first direction intersects with the second direction;
the fourth segment is located in a film layer within the base plate that is closer to the substrate than the third segment;
the driving circuit comprises a transistor, the transistor comprises a semiconductor structure, a gate located on a side of the semiconductor structure away from the substrate, and a source-drain located on a side of the gate away from the substrate,
at least a portion of the third segment is disposed in the same layer as the source/drain, at least a portion of the third segment is located in a film layer within the base plate on a side of the source-drain away from the substrate, at least a portion of the fourth segment is disposed in the same layer as the gate, at least a portion of the fourth segment is located in a film layer within the base plate between the gate and the source/drain;
the base plate further comprises a light-shielding structure disposed on a side of the substrate, the light-shielding structure is formed with a light-shielding space, the light-shielding structure is provided with a communication opening, the driving circuit and the fourth segment are located within the light-shielding space, and the third segment extends from outside the light-shielding space into the light-shielding space via the communication opening.

11. The display panel according to claim 10, wherein the number of the second type of signal lines is multiple, the third segments of at least two adjacent second type of signal lines are disposed in different layers, and the first type of signal lines located between adjacent driving circuits within the second region and the third segments of the second type of signal lines are disposed in different layers;
orthographic projections of the third segments of at least two second type of signal lines on the substrate at least partially overlap;
orthographic projections of the first type of signal lines located between adjacent driving circuits within the second region on the substrate at least partially overlap with orthographic projections of the third segments of the second type of signal lines on the substrate.

12. The display panel according to claim 1, further comprising a circuit column, the circuit column comprises the driving circuits located in the same column in the first direction within the first region,
the base plate further comprises a third type of signal line, a single third type of signal line is connected to two driving circuits located on both sides of the second region in the first direction within the circuit column, and the third type of signal line is connected to at least one driving circuit within the circuit column;
the third type of signal line comprises a fifth segment and a sixth segment connected to each other, an orthographic projection of the fifth segment on the substrate partially overlaps with an orthographic projection of the first type of signal line on the substrate, the sixth segment is connected to at least one driving circuit within the second region, and an orthographic projection of the sixth segment on the substrate partially overlaps with an orthographic projection of the second type of signal line on the substrate, wherein the fifth segment and the first type of signal line are at least partially disposed in different layers, and the sixth segment and the second type of signal line are at least partially disposed in different layers;
the sixth segment is connected to the driving circuit within the first region via the fifth segment, and adjacent sixth segments in the first direction are connected via the fifth segment.

13. The display panel according to claim 12, wherein the driving circuit comprises a transistor, the transistor comprises a semiconductor structure, a gate located on a side of the semiconductor structure away from the substrate, and a source/drain electrode located on a side of the gate away from the substrate,
at least a portion of the fifth segment is disposed in a same layer as the source/drain electrode, at least a portion of the fifth segment is located in a film layer within the base plate on a side of the source/drain electrode away from the substrate, and at least a portion of the sixth segment is disposed in a same layer as the source-drain electrode.

14. The display panel according to claim 1, wherein a light transmittance of the display panel in the second region is greater than a light transmittance of the display panel in the first region;
an arrangement density of the driving circuits in the second region is less than an arrangement density of the driving circuits in the first region, and
an arrangement density of the light-emitting devices in the second region is less than an arrangement density of the light-emitting devices in the first region.

15. A display panel, having a first region and a second region, the display panel comprising:
a base plate, comprising a substrate, and a plurality of driving circuits, first-type signal lines and second-type signal lines disposed on a same side of the substrate;
a plurality of light-emitting devices, disposed on a side of the base plate, the driving circuits being connected to the light-emitting devices,
wherein the driving circuits and the light-emitting devices are disposed in both the first region and the second region, at least portions of the first-type signal lines and the second-type signal lines are disposed in the second region,
the first-type signal lines are spaced apart from the driving circuits in the second region, the second-type signal lines are connected to at least one of the driving circuits in the second region, a part of the second-type signal line and another part of the second-type signal line are disposed in different layers within the second region, and
a part of the first-type signal line and another part of the second-type signal line are disposed in different layers within the second region.

16. The display panel according to claim 15, wherein at least portions of the first-type signal lines in the second region and at least portions of the second-type signal lines in the second region are disposed in a same layer,
at least portions of the first-type signal lines in the second region and at least portions of the second-type signal lines in the second region are disposed in a same layer,
wherein the second-type signal lines comprise a third segment and a fourth segment located in the second region and connected to each other, the third segment and the fourth segment are disposed in different layers,
the base plate further comprises a light-shielding structure disposed on a side of the substrate, the light-shielding structure is formed with a light-shielding space, the light-shielding structure is provided with a communication opening, the driving circuits and the fourth segment are located within the light-shielding space, and the third segment extends from outside the light-shielding space into the light-shielding space via the communication opening.

17. The display panel according to claim 15, wherein the first-type signal lines comprise a first segment and a second segment located in the second region and connected to each other, the first segment is connected to the driving circuits in the first region, and the first segment is located between the driving circuits adjacent in a first direction within the second region,
a minimum distance between the second segment and the driving circuits on one side in the first direction is less than a minimum distance between the second segment and another driving circuits on another side in the first direction.

18. The display panel according to claim 17, further comprising a circuit group located in the second region, the circuit group comprises at least one of the driving circuits, a number of the circuit groups is plural, the plurality of circuit groups are arrayed in the first direction and a second direction, the first-type signal lines are disposed surrounding at least a part of the circuit groups, wherein the first direction intersects the second direction;
at least one of the second-type signal lines is connected to at least two of the circuit groups adjacent in the second direction; each of the circuit groups corresponds to a repeated pixel unit group, the repeated pixel unit group comprises a plurality of light-emitting devices, and the circuit group comprises a plurality of driving circuits correspondingly disposed with the light-emitting devices.

19. A display panel, having a first region and a second region, the display panel comprising:
a base plate, comprising a substrate, and a plurality of driving circuits, first-type signal lines and second-type signal lines disposed on a same side of the substrate;
a light-shielding structure, disposed on a side of the base plate, the light-shielding structure is formed with a light-shielding space, the driving circuits are located within the light-shielding space;
a plurality of light-emitting devices, disposed on a side of the base plate, the driving circuits being connected to the light-emitting devices,
wherein the driving circuits and the light-emitting devices are disposed in both the first region and the second region, at least portions of the first-type signal lines and the second-type signal lines are disposed in the second region,
the first-type signal lines are spaced apart from the driving circuits in the second region, and the first-type signal lines are located outside the light-shielding space, the light-shielding structure is provided with a communication opening, the second-type signal lines extend from outside the light-shielding space into the light-shielding space via the communication opening, the second-type signal lines are connected to at least one of the driving circuits in the second region,
the first-type signal lines comprise a first segment and a second segment located in the second region and connected to each other, the first segment is connected to the driving circuits in the first region, and the first segment is located between the light-shielding structures adjacent in a first direction within the second region,
a minimum distance between the second segment and the light-shielding structure on one side in the first direction is less than a minimum distance between the second segment and another light-shielding structure on another side in the first direction, and a compensation capacitor is formed between adjacent ones of the second segment and the light-shielding structure.

20. The display panel according to claim 19, wherein an orthographic projection of the first type of signal line on the substrate partially overlaps with an orthographic projection of the light-shielding structure on the substrate;
the light-shielding structure comprises a light-shielding main body and a protruding structure disposed on a side of the light-shielding main body away from the light-shielding space, and
an orthographic projection of the first type of signal line on the substrate partially overlaps with an orthographic projection of the protruding structure on the substrate;
a second segment and the adjacent protruding structure has a compensation capacitor formed therebetween;
the driving circuit comprises a transistor, the transistor comprises a semiconductor structure, a gate located on a side of the semiconductor structure away from the substrate, and a source/drain located on a side of the gate away from the substrate,
at least a portion of the second segment is disposed in the same layer as the gate, at least a portion of the protruding structure is located in a film layer between the semiconductor structure within the base plate and the substrate, and at least a portion of the protruding structure is located in a film layer between the gate within the base plate and the source/drain.
